(19) United States
(12) Patent Application Publication
(10) Pub. No.: US 2026/0190725 A1
(43) Pub. Date: Jul. 2, 2026

(54) Display Device

(71) Applicant: LG Display Co., Ltd., Seoul (KR)

(72) Inventor: Subin Kim, Gumi-si (KR)

(21) Appl. No.: 19/425,175

(22) Filed: Dec. 18, 2025

(30) Foreign Application Priority Data
Dec. 30, 2024 (KR) 10-2024-0201366

(51) Int. Cl. H10K 59/131; H10K 59/40; H10K 59/80; H10K 59/88

(52) U.S. Cl. CPC H10K 59/1315; H10K 59/40; H10K 59/873; H10K 59/88

(57) ABSTRACT

A display device presented herein includes: a substrate including an active area and a non-active area, an encapsulation layer disposed on the substrate, a plurality of pseudo lines disposed in the non-active area, and an amplifier connected to a subset of the plurality of pseudo lines. The subset of the plurality of pseudo lines are disposed outside the encapsulation layer in the non-active area, and a remainder of the plurality of pseudo lines not in the subset of the plurality of pseudo lines are disposed on the encapsulation layer in the non-active area. By connecting the amplifier to the pseudo line, the signal radiation amount of the pseudo line can be increased, and touch signal noise due to electromagnetic interference can be reduced.

### CROSS-REFERENCE TO RELATED APPLICATION

The present application claims the priority to Republic of Korea Patent Application No. 10-2024-0201366, filed on Dec. 30, 2024, which is incorporated herein by reference in its entirety.

### BACKGROUND

### Field

The present disclosure relates to a display device, and more particularly, to a display device having a built-in touch unit.

### Discussion of the Related Art

An electroluminescent display device is a self-luminous display. Unlike a liquid crystal display device, the electroluminescent display device does not require a separate light source and can be manufactured in lightweight, thin designs. Furthermore, the electroluminescent display device is advantageous in terms of power consumption due to low-voltage operation, has excellent color expression, response speed, viewing angle, and contrast ratio (CR), and is being studied as next-generation displays.

Among the electroluminescent display devices, there are touchscreen-integrated display devices that include a touch unit capable of recognizing the user's touch. The touchscreen-integrated display devices allow direct input of information using a finger or pen, and are widely used in navigation systems, portable terminals, and home appliances.

### SUMMARY

An object to be achieved by the present disclosure is to provide a display device having a built-in touch unit.

Another object to be achieved by the present disclosure is to provide a display device with improved performance of a touch unit.

Still another object to be achieved by the present disclosure is to provide a display device that reduces electromagnetic interference of a touch unit.

Still another object to be achieved by the present disclosure is to provide a display device that suppresses disconnection of the line in the area of a dam member.

Still another object to be achieved by the present disclosure is to provide a display device with reduced capacitance variation in a touch line.

Still another object to be achieved by the present disclosure is to provide a display device having improved touch sensing performance by forming a dummy touch electrode between a plurality of touch electrodes.

Still another object to be achieved by the present disclosure is to provide a display device that minimizes or at least reduces the transmission delay of touch signals.

Still another object to be achieved by the present disclosure is to provide a display device that suppresses radiation loss of a pseudo line due to coupling with a set cover.

Still another object to be achieved by the present disclosure is to provide a display device that improves the noise reduction effect of a pseudo line.

Objects of the present disclosure are not limited to the above-mentioned objects, and other objects, which are not mentioned above, can be clearly understood by those skilled in the art from the following descriptions.

A display device according one or more embodiments of the present disclosure includes: a substrate including an active area and a non-active area; an encapsulation layer disposed on the substrate; a plurality of pseudo lines disposed in the non-active area; and an amplifier connected to some of the plurality of pseudo lines, in which some of the plurality of pseudo lines are disposed outside the encapsulation layer in the non-active area, and the remainder of the plurality of pseudo lines is disposed on the encapsulation layer in the non-active area. Accordingly, by connecting the amplifier to the pseudo line, the signal radiation amount of the pseudo line can be increased, and touch signal noise due to electromagnetic interference can be improved.

A display device according to one or more other embodiments of the present disclosure includes: a substrate including an active area and a non-active area; a plurality of light-emitting diodes disposed on the substrate; an encapsulation layer disposed on the plurality of light-emitting diodes and extending from the active area to a portion of the non-active area; and a touch unit disposed on the encapsulation layer and the substrate, in which the touch unit includes a plurality of touch electrodes on the encapsulation layer, a plurality of touch lines connected to the plurality of touch electrodes, and a plurality of pseudo lines disposed in the non-active area, and the plurality of pseudo lines are disposed to enclose the plurality of touch lines and the plurality of touch electrodes. Therefore, the performance of the touch unit can be reduced by forming pseudo lines that suppress electromagnetic interference by external signals.

Other detailed matters of the embodiments are included in the detailed description and the drawings.

According to the present disclosure, a display device having a built-in touch unit can be provided.

According to the present disclosure, a display device with improved performance of a touch unit can be provided.

According to the present disclosure, the electromagnetic interference in the touch unit can be reduced by including a pseudo line.

According to the present disclosure, it is possible to suppress disconnection of the touch line in a dam member.

According to the present disclosure, capacitance variation in the touch line can be reduced by varying the width of the touch line.

According to the present disclosure, touch sensing performance can be reduced by forming a dummy touch electrode between the plurality of touch electrodes.

According to the present disclosure, the transmission delay of the touch signal can be minimized or at least reduced.

According to the present disclosure, the radiation reduction of a pseudo line due to coupling between the pseudo line and the set cover can be suppressed.

According to the present disclosure, the noise reduction effect of the pseudo line can be improved.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to one or more embodiments of the present disclosure.

FIG. 2 is a schematic plan view of the display device according to one or more embodiments of the present disclosure.

FIG. 3 is a cross-sectional view of a sub-pixel of the display device according to one or more embodiments of the present disclosure.

FIG. 4 is an enlarged plan view of an area A1 of FIG. 2.

FIG. 5A is a cross-sectional view taken along line A-A′ of FIG. 2.

FIG. 5B is a cross-sectional view taken along line B-B′ of FIG. 2.

FIGS. 6A to 6C are schematic cross-sectional views of a dam member of the display device according to one or more embodiments of the present disclosure.

FIG. 7 is an enlarged plan view of an area A2 of FIG. 2.

FIGS. 8 and 9 are schematic plan views of a touch unit of the display device according to one or more embodiments of the present disclosure.

FIG. 10 is a schematic enlarged plan view of the touch unit of the display device according to one or more embodiments of the present disclosure.

FIG. 11 and FIG. 12 are schematic enlarged plan views of the touch unit of the display device according to one or more embodiments of the present disclosure.

FIG. 13 is a schematic plan view of a display device according to one or more embodiments of the present disclosure.

FIGS. 14 and 15 are enlarged plan views of an area A3 of FIG. 13.

FIG. 16 is an enlarged plan view of an area A4 of FIG. 14.

FIG. 17 is a cross-sectional view taken along line C-C′ of FIG. 16.

FIG. 18 is an enlarged plan view of an area A5 of FIG. 16.

FIG. 19 is an enlarged plan view of an area A6 of FIG. 13.

FIG. 20 is a cross-sectional view taken along line D-D′ of FIG. 19.

FIG. 21 is an enlarged plan view of an area A7 of FIG. 14.

FIG. 22A is an enlarged plan view of an area A8 of FIG. 14.

FIG. 22B is a cross-sectional view taken along line E-E′ of FIG. 22A.

FIG. 23A is an enlarged plan view of an area A8 of FIG. 14.

FIG. 23B is a cross-sectional view taken along line F-F′ of FIG. 23A.

FIG. 24 is a schematic plan view of a display device according to one or more other embodiments of the present disclosure.

FIG. 25 is a cross-sectional view taken along line G-G′ of FIG. 24.

FIG. 26 is a schematic diagram of a display device according to one or more other embodiments of the present disclosure.

FIG. 27A is a graph measuring noise of a touch signal caused by electromagnetic interference of a display device according to a comparative example.

FIG. 27B is a graph measuring noise of a touch signal caused by electromagnetic interference of a display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and embodiments of the present disclosure can be carried out independently of or in association with each other.

Hereinafter, a display device according to embodiments of the present disclosure will be described in detail with reference to accompanying drawings.

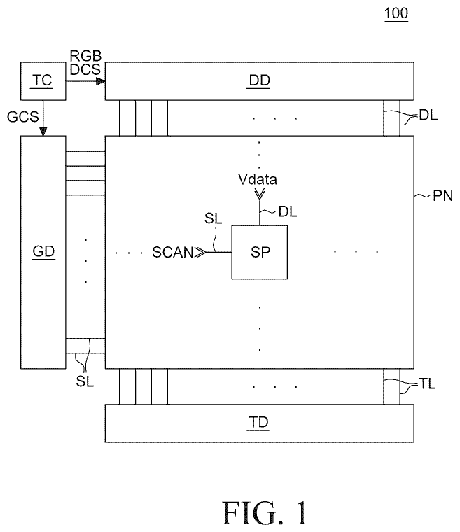

FIG. 1 is a schematic diagram of a display device according to one or more embodiments of the present disclosure. For convenience of explanation, in FIG. 1, only a display panel PN, a gate driver GD, a data driver DD, a touch driver TD, and a timing controller TC among the various components of a display device 100 are illustrated.

Referring to FIG. 1, the display device 100 includes the display panel PN including a plurality of sub-pixels SP, the gate driver GD and the data driver DD that supply various signals to the display panel PN, the timing controller TC that controls the gate driver GD and the data driver DD, and the touch driver TD for sensing a touch input.

The display panel PN is configured to display images to a user and includes the plurality of sub-pixels SP. In the display panel PN, a plurality of scan lines SL and a plurality of data lines DL intersect each other, and each of the plurality of sub-pixels SP is connected to the scan line SL and the data line DL. In addition, although not illustrated in the drawings, each of the plurality of sub-pixels SP may be connected to a high-potential power line, a low-potential power line, a reference line, or the like.

The plurality of sub-pixels SP is the minimum units that constitute a screen, and each of the plurality of sub-pixels SP includes a light-emitting diode and a pixel circuit for driving the light-emitting diode. The plurality of light-emitting diodes may be defined differently depending on the type of the display device 100. For example, when the display device 100 is an organic light-emitting display device 100, the light-emitting diode may be an organic light-emitting diode (OLED).

The gate driver GD supplies a plurality of scan signals SCAN to the plurality of scan lines SL according to a plurality of gate control signals GCS provided from the timing controller TC. In FIG. 1, one gate driver GD is illustrated as being spaced apart from one side of the display panel PN, but the number and disposition of the gate drivers GD are not limited thereto.

The data driver DD converts image data RGB transmitted from the timing controller TC into data voltage Vdata using a reference gamma voltage according to a plurality of data control signals DCS provided from the timing controller TC. The data driver DD may supply the converted data voltage Vdata to the plurality of data lines DL.

The timing controller TC aligns the image data RGB input from the outside and supplies the image data RGB to the data driver DD. The timing controller TC may generate the gate control signal GCS and the data control signal DCS using externally input synchronization signals, such as a dot clock signal, a data enable signal, and a horizontal/vertical synchronization signal. In addition, the timing controller TC may control the gate driver GD and the data driver DD by supplying the generated gate control signal GCS and data control signal DCS to the gate driver GD and the data driver DD, respectively.

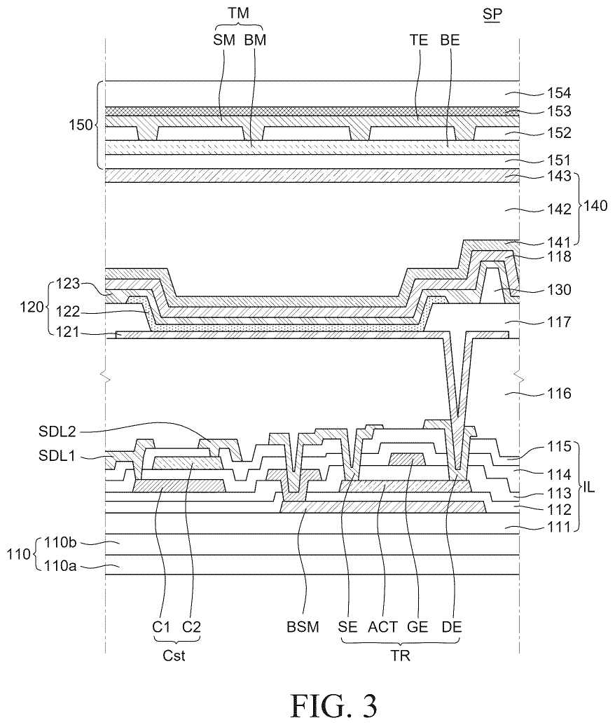

The touch driver TD is connected to the display panel PN through a a touch line TL, and drives the touch unit 150 (referring to FIG. 3) included in the display panel PN during the touch sensing period based on a touch enable signal input from the timing controller TC or the external component. The touch driver TD may sense a touch input based on a signal from the touch unit 150.

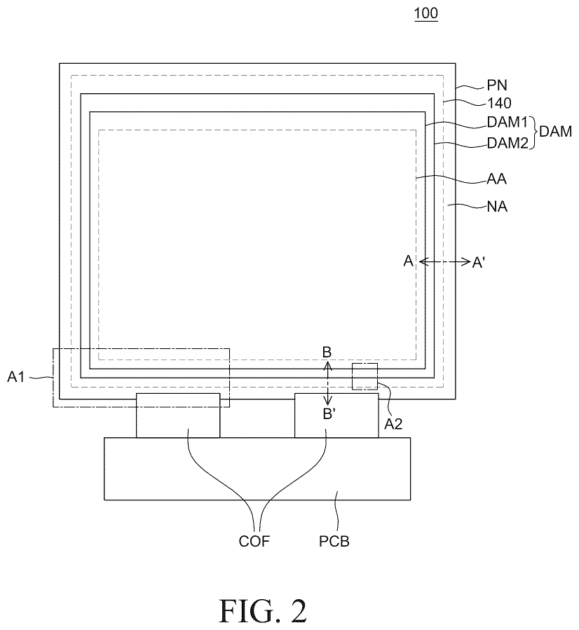

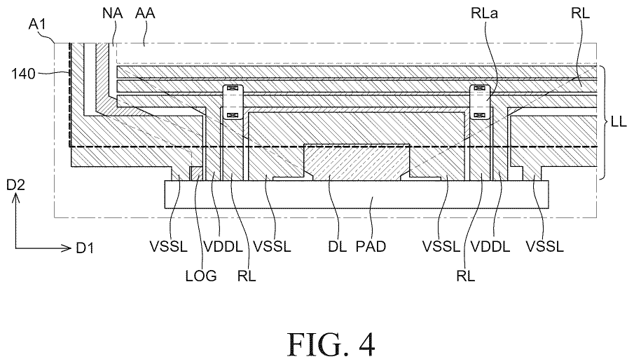

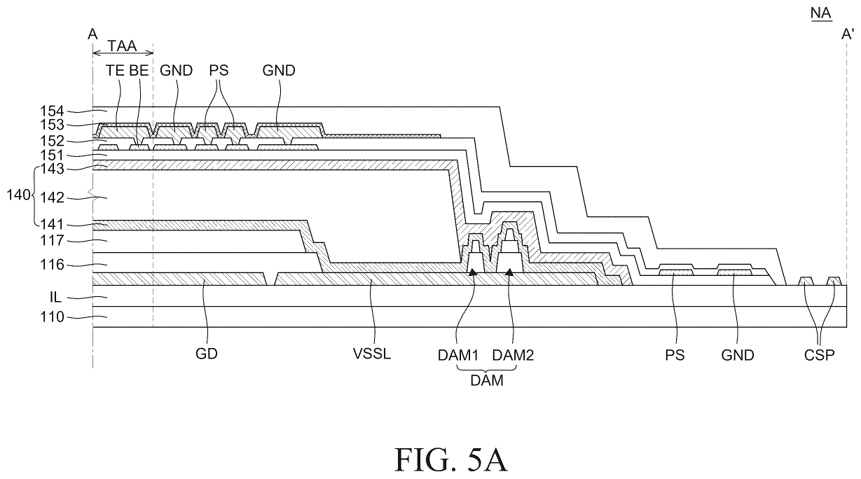

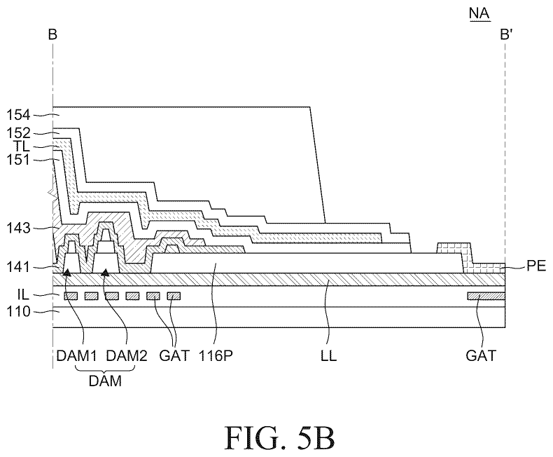

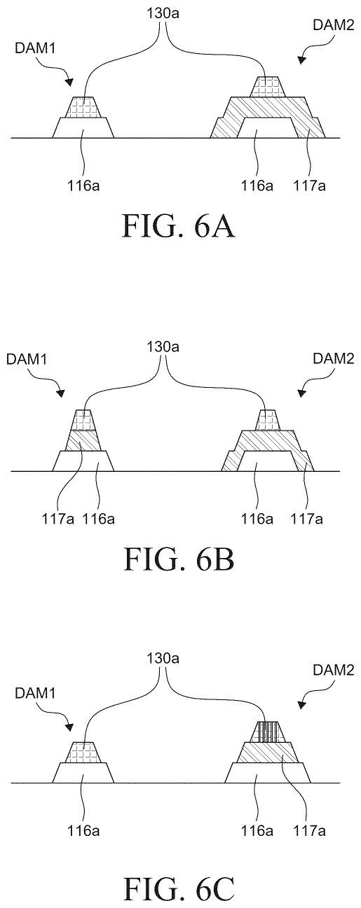

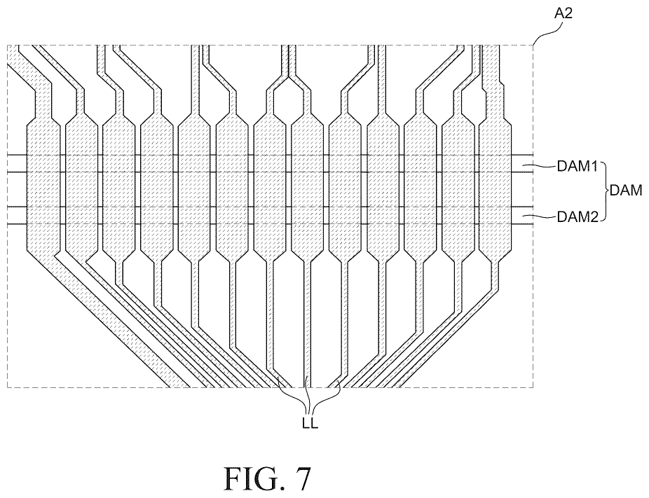

FIG. 2 is a schematic plan view of the display device according to one or more embodiments of the present disclosure. FIG. 3 is a cross-sectional view of a sub-pixel of the display device according to one or more embodiments of the present disclosure. FIG. 4 is an enlarged plan view of an area A1 of FIG. 2. FIG. 5A is a cross-sectional view taken along line A-A′ of FIG. 2. FIG. 5B is a cross-sectional view taken along line B-B′ of FIG. 2. FIGS. 6A to 6C are schematic cross-sectional views of a dam member of a display device according to one or more embodiments of the present disclosure. FIG. 7 is an enlarged plan view of an area A2 of FIG. 2. For convenience of explanation, only a low-potential power line VSSL, a high-potential power line VDDL, a reference line RL, a LOG line LOG, and a data line DL among a plurality of lines are illustrated in FIG. 4.

Referring to FIG. 2, the display panel PN of the display device 100 includes an active area AA and a non-active area NA. The active area AA may be an area where an image is displayed. The plurality of sub-pixels SP may be formed in the active area AA to display an image. The non-active area NA may be an area where an image is not displayed. Various lines and circuits for driving the plurality of sub-pixels SP of the active area AA may be disposed in the non-active area NA. For example, the gate driver GD may be mounted in the non-active area NA, or a pad portion PAD on which a flexible film COF and a printed circuit board PCB are bonded may be disposed in the non-active area NA. In addition, wiring lines for driving the plurality of sub-pixels SP, the gate driver GD, the touch unit 150, or the like may be disposed in the non-active area NA.

A plurality of flexible films COF is connected to the pad portion PAD of the display panel PN. The plurality of flexible films COF may be a film in which various components are disposed on a flexible base film. For example, a driving integrated circuit (IC) may be disposed on the plurality of flexible films COF. The driving IC may be a component that processes data and driving signals for displaying an image. The plurality of flexible films COF may be attached or bonded to a plurality of pad electrodes PE via a conductive adhesive layer, but embodiments of the present disclosure are not limited thereto.

The printed circuit board PCB is connected to a plurality of flexible films COF. The printed circuit board PCB is electrically connected to the flexible films COF and may be a component that supplies signals to a driving IC. Various components for supplying various signals to the driving ICs may be disposed on the printed circuit board PCB. For example, various components such as the timing controller TC, a power management integrated circuit (PMIC), a memory, or a processor may be disposed on the printed circuit board PCB, but embodiments of the present disclosure are not limited thereto.

Referring to FIG. 3, the substrate 110 is a support member for supporting other components of the display device 100 and may be made of an insulating material. For example, the substrate 110 may be made of glass, resin, or the like.

The substrate 110 may be formed of one or more layers. For example, the substrate 110 may be formed of a bilayer structure including a first substrate 110a and a second substrate 110b on the first substrate 110a. For example, the first substrate 110a and the second substrate 110b may be formed of polyimide (PI). In addition, although not illustrated in the drawing, an insulating layer may be further disposed between the first substrate 110a and the second substrate 110b.

A multi-buffer layer 111 is disposed on a substrate 110. The multi-buffer layer 111 may reduce the penetration of moisture or impurities through the substrate 110. For example, the multi-buffer layer 111 may be composed of a single layer or a plurality of layers of an insulating material such as silicon nitride (SiNx), silicon oxide (SiOx), and silicon oxynitride (SiON), but is not limited thereto.

A light-shielding layer BSM is disposed on the multi-buffer layer 111. The light-shielding layer BSM may minimize or at least reduce leakage current of a plurality of transistors TR by blocking light incident on an active layer ACT of a transistor TR from the lower portion of the substrate 110. In addition, the light-shielding layer BSM may minimize or at least reduce damage to the plurality of transistors TR caused by charges trapped in the substrate 110. The light-shielding layer BSM may be connected to a source electrode SE or a drain electrode DE of the transistor TR so as to minimize or at least reduce its influence on a threshold voltage of the transistor TR. The light-shielding layer BSM may be formed as a single layer or a plurality of layers made of, for example, one of molybdenum (Mo), copper (Cu), titanium (Ti), aluminum (Al), chromium (Cr), gold (Au), nickel (Ni), and neodymium (Nd), or an alloy thereof, but is not limited thereto.

An active buffer layer 112 is disposed on the light-shielding layer BSM. The active buffer layer 112 may protect the transistor TR from impurities such as alkali ions leaking from the substrate 110. In addition, the active buffer layer 112 may improve adhesion between layers formed above the active buffer layer 112 and the substrate 110. For example, the active buffer layer 112 may be formed of a single layer or a plurality of layers of an insulating material such as silicon nitride (SiNx), silicon oxide (SiOx), and silicon oxynitride (SiON), but is not limited thereto.

The transistor TR is disposed on the active buffer layer 112. The transistor TR includes the active layer ACT, a gate electrode GE, the source electrode SE, and the drain electrode DE.

First, the active layer ACT is disposed on the active buffer layer 112. The active layer ACT may be made of a semiconductor material such as an oxide semiconductor, amorphous silicon, or polysilicon, but is not limited thereto.

A gate insulating layer 113 is disposed on the active layer ACT. The gate insulating layer 113 is an insulating layer for insulating the active layer ACT and the gate electrode GE, and may be composed of a single layer or a plurality of layers of silicon oxide (SiOx) or silicon nitride (SiNx), but is not limited thereto.

The gate electrode GE is disposed on the gate insulating layer 113. The gate electrode GE may be a single layer or a plurality of layers made of a conductive material, for example, one of molybdenum (Mo), aluminum (Al), chromium (Cr), gold (Au), titanium (Ti), nickel (Ni), neodymium (Nd), and copper (Cu), or an alloy thereof, but is not limited thereto.

A first interlayer insulating layer 114 is disposed on the gate electrode GE, and a second interlayer insulating layer 115 is disposed on the first interlayer insulating layer 114. The first interlayer insulating layer 114 and the second interlayer insulating layer 115 are insulating layers for protecting the underlying structure, and may be composed of a single layer or a plurality of layers of silicon oxide (SiOx) or silicon nitride (SiNx), but are not limited thereto. As shown in FIG. 3, the multi-buffer layer 111, the active buffer layer 112, the gate insulating layer 113, the first interlayer insulating layer 114, and the second interlayer insulating layer 115 may be collectively referred to as an insulating layer group IL.

The source electrode SE and the drain electrode DE are disposed on the second interlayer insulating layer 115. The source electrode SE and the drain electrode DE can be electrically connected to the active layer ACT through contact holes formed in the second interlayer insulating layer 115, the first interlayer insulating layer 114, and the gate insulating layer 113. The source electrode SE and the drain electrode DE may be formed of a single layer or multilayer structure of a conductive material, for example, copper (Cu), aluminum (Al), molybdenum (Mo), nickel (Ni), titanium (Ti), gold (Au), chromium (Cr), or an alloy thereof, but are not limited thereto.

A capacitor Cst is disposed on the gate insulating layer 113. The capacitor Cst may include a first capacitor electrode C1 and a second capacitor electrode C2. The first capacitor electrode C1 may be disposed on the gate insulating layer 113, and the second capacitor electrode C2 may be disposed on the first interlayer insulating layer 114. The first capacitor electrode C1 and the second capacitor electrode C2 may overlap each other with the first interlayer insulating layer 114 interposed therebetween. For example, the first capacitor electrode C1 and the second capacitor electrode C2 may be a single layer or plurality of layers made of any one of molybdenum (Mo), aluminum (Al), chromium (Cr), gold (Au), titanium (Ti), nickel (Ni), neodymium (Nd), and copper (Cu), or an alloy thereof, but is not limited thereto.

Meanwhile, various conductive layers may be further disposed on the substrate 110. The various conductive layers may constitute any one of a plurality of wiring lines, a plurality of transistors TR, and a plurality of capacitors Cst. For example, a first source-drain conductive layer SDL1 and a second source-drain conductive layer SDL2 may be disposed on the second interlayer insulating layer 115. The first source-drain conductive layer SDL1 may be connected to the first capacitor electrode C1, and the second source-drain conductive layer SDL2 may be connected to the second capacitor electrode C2. Each of the first source-drain conductive layer SDL1 and the second source-drain conductive layer SDL2 may function as an electrode that connects the first capacitor electrode C1 and the second capacitor electrode C2 to other components of the sub-pixel SP.

A planarization layer 116 is disposed on the transistor TR. The planarization layer 116 is an insulating layer that planarizes the upper portion of the substrate 110. The planarization layer 116 may be made of an organic material, and may be composed of a single layer or plurality of layers of an organic material such as polyimide or photo acryl, but is not limited thereto.

A light-emitting diode 120 is disposed on the planarization layer 116. The light-emitting diode 120 may be an organic light-emitting diode (OLED). The light-emitting diode 120 includes an anode 121, a light-emitting layer 122, and a cathode 123.

The anode 121 is disposed on the planarization layer 116. The anode 121 may be connected to the drain electrode DE of the transistor TR. The anode 121 may be formed of a conductive material having a high work function to supply holes to the light-emitting layer 122. For example, the anode 121 may be formed of a transparent conductive material such as indium tin oxide (ITO), or indium zinc oxide (IZO), but is not limited thereto.

Meanwhile, the display device 100 may be implemented in a top emission or bottom emission manner. In the case of the top emission manner, a reflective layer may be disposed below the anode 121 to reflect light emitted from the light-emitting layer 122 toward the cathode 123. For example, the reflective layer may include a material with excellent reflectivity, such as aluminum (Al) or silver (Ag), but is not limited thereto. Conversely, in the case of the bottom emission manner, the anode 121 may be formed only of a transparent conductive material. Hereinafter, the display device 100 according to one or more embodiments of the present disclosure will be described assuming that the display device 100 is implemented in the top emission manner.

A bank 117 is disposed on the anode 121 and the planarization layer 116. The bank 117 may cover the edge of the anode 121. The bank 117 may partition the plurality of sub-pixels SP and suppress color mixing between the plurality of sub-pixels SP. The bank 117 may be an organic insulating material. For example, the bank 117 may be made of any one of polyimide, acrylic, and benzocyclobutene (BCB)-based resins, but is not limited thereto.

A spacer 130 is disposed on the bank 117. The spacer 130 may suppress damage to the light-emitting diode 120 that may occur when a fine metal mask (FMM) used to form the light-emitting layer 122 of the light-emitting diode 120 directly contacts the bank 117 or the anode 121. The spacer 130 may be made of the same material as the bank 117 or may be made of an insulating material different from the bank 117, but is not limited thereto. In addition, the spacer 130 and the bank 117 may be formed integrally at once. Since the spacer 130 is disposed on the bank 117, the cathode 123 may be disposed to cover the spacer 130 and the bank 117.

The light-emitting layer 122 is disposed on the anode 121 and the bank 117. The light-emitting layer 122 may be an organic layer for emitting light of a specific color. The light-emitting layer 122 may further include various layers such as a hole transport layer, a hole injection layer, a hole blocking layer, an electron injection layer, an electron blocking layer, or an electron transport layer. The light-emitting layer 122 may be separately formed for each sub-pixel SP so that each sub-pixel SP may emit a different color. For example, the light-emitting layer 122 for red, the light-emitting layer 122 for green, and the light-emitting layer 122 for blue may be separately formed for each sub-pixel SP. Meanwhile, the light-emitting layer 122 for emitting white light may be commonly formed for the plurality of sub-pixels SP, and a light conversion member for converting the white light into light of various colors may be separately provided, but embodiments of the present disclosure are not limited thereto.

The cathode 123 is disposed on the light-emitting layer 122. The cathode 123 may be formed as a single layer across the entire surface of the substrate 110. That is, the cathode 123 may be a common layer formed in common for the plurality of sub-pixels SP. Since the cathode 123 supplies electrons to the light-emitting layer 122, the cathode 123 may be formed of a conductive material having a low work function. The cathode 123 may be formed of, for example, a transparent conductive material such as indium tin oxide (ITO) or indium zinc oxide (IZO), a metal alloy such as MgAg, an ytterbium (Yb) alloy, or the like, and may further include a metal doping layer, but is not limited thereto.

A protective layer 118 is disposed on the cathode 123. The protective layer 118 may protect the light-emitting diode 120 from foreign substances or moisture infiltration. For example, the protective layer 118 may be made of an inorganic material such as aluminum oxide (Al₂O₃) or silicon nitride (SiNx).

An encapsulation layer 140 is disposed on the protective layer 118. The encapsulation layer 140 may protect the light-emitting diode 120 from moisture or the like penetrating from the outside of the display device 100. The encapsulation layer 140 includes a first inorganic encapsulation layer 141, an organic encapsulation layer 142, and a second inorganic encapsulation layer 143.

The first inorganic encapsulation layer 141 is disposed on the protective layer 118, and the second inorganic encapsulation layer 143 is disposed on the first inorganic encapsulation layer 141. The first inorganic encapsulation layer 141 and the second inorganic encapsulation layer 143 may serve to block the penetration of moisture or oxygen. The first inorganic encapsulation layer 141 and the second inorganic encapsulation layer 143 may be made of an inorganic material, and for example, may be made of an inorganic material such as silicon nitride (SiNx), silicon oxide (SiOx), or aluminum oxide (AlOx), but are not limited thereto.

The organic encapsulation layer 142 is disposed between the first inorganic encapsulation layer 141 and the second inorganic encapsulation layer 143. The organic encapsulation layer 142 may be formed to a thickness thicker than the first inorganic encapsulation layer 141 and the second inorganic encapsulation layer 143 so as to adsorb and block foreign substances (particles) that may occur during the manufacturing process of the display device 100. The organic encapsulation layer 142 may fill cracks that may occur in the first inorganic encapsulation layer 141 and the second inorganic encapsulation layer 143, and cover foreign substances on the first inorganic encapsulation layer 141 to flatten the upper portion. The organic encapsulation layer 142 may be made of an organic material, and may be made of, for example, an epoxy-based polymer or an acrylic-based polymer, but is not limited thereto.

The touch unit 150 is disposed on the encapsulation layer 140. The touch unit 150 may sense an external touch input using a user's finger or a touch pen, or the like. The touch unit 150 includes a touch buffer layer 151, a bridge electrode BE, a touch electrode TE, a touch insulation layer 152, a touch passivation layer 153, and a touch protection layer 154.

First, the touch buffer layer 151 is disposed on the encapsulation layer 140. The touch buffer layer 151 is an insulating layer for protecting peripheral components such as the encapsulation layer 140 and the light-emitting diode 120 during the formation process of the touch unit 150. The touch buffer layer 151 may minimize or at least reduce the penetration of moisture from the outside, materials used in the manufacturing process of the touch unit 150, or the like into the light-emitting diode 120. For example, the touch buffer layer 151 may be made of an insulating material such as silicon oxide (SiOx) or silicon nitride (SiNx), but is not limited thereto.

A plurality of bridge electrodes BE are disposed on a touch buffer layer 151. The plurality of bridge electrodes BE is electrodes made of a bridge metal BM and may connect a plurality of touch electrodes TE to each other. For example, a pair of adjacent touch electrodes TE among the plurality of touch electrodes TE may be electrically connected to each other through the bridge electrodes BE. For example, the plurality of bridge electrodes BE may be formed of a metal material such as copper (Cu), aluminum (Al), titanium (Ti), chromium (Cr), nickel (Ni), or a laminated structure of a metal material such as titanium/aluminum/titanium (Ti/Al/Ti), but is not limited thereto.

The touch insulation layer 152 is disposed on the bridge electrode BE. The touch insulation layer 152 is disposed between the plurality of bridge electrodes BE and the plurality of touch electrodes TE, and may insulate some of the bridge electrodes BE and some of the touch electrodes TE. The touch insulation layer 152 may be made of an insulating material such as silicon oxide (SiOx) or silicon nitride (SiNx), but is not limited thereto.

The plurality of touch electrodes TE is disposed on a touch insulation layer 152. The plurality of touch electrodes TE is electrodes made of a sensor metal SM and are electrodes for sensing a touch input. For example, when the touch unit 150 senses a touch input in a mutual capacitance manner, the plurality of touch electrodes TE may be made of a touch driving electrode to which a touch driving signal is applied and a touch sensing electrode that forms a capacitance with the touch driving electrode. In addition, the touch input may be sensed based on a change in capacitance between the touch driving electrode and the touch sensing electrode. Here, the bridge metal BM and the sensor metal SM may be collectively referred to as a touch metal TM.

However, the touch sensing method of the touch unit 150 is exemplary, and the touch unit 150 may sense touch input using a self-capacitance method, but is not limited thereto.

The touch passivation layer 153 is disposed on the plurality of touch electrodes TE. The touch passivation layer 153 is an insulating layer for protecting the plurality of touch electrodes TE and the plurality of bridge electrodes BE, and can suppress corrosion of the plurality of touch electrodes TE and the plurality of bridge electrodes BE caused by external moisture, or the like. For example, the touch passivation layer 153 may be made of an insulating material such as silicon oxide (SiOx) or silicon nitride (SiNx), but is not limited thereto.

The touch protection layer 154 is disposed on the touch passivation layer 153. The touch protection layer 154 may protect the plurality of touch electrodes TE and the plurality of bridge electrodes BE from external moisture or impact together with the touch passivation layer 153. For example, the touch protection layer 154 may be made of an organic material such as an epoxy-based or acrylic-based polymer, but is not limited thereto.

Meanwhile, in the drawing, the touch passivation layer 153 is depicted as being disposed below the touch protection layer 154, but the touch passivation layer 153 may also be formed on the touch protection layer 154, and is not limited thereto.

Referring to FIG. 4, the pad portion PAD and the plurality of wiring lines are disposed in the non-active area NA.

The pad portion PAD is a portion electrically connected to a plurality of flexible films COF, and may include a plurality of pad electrodes PE and a plurality of touch pad electrodes TPE. Each of the plurality of pad electrodes PE may transmit signals from the printed circuit board PCB and the flexible film COF to various wiring lines of the display panel PN. In addition, the plurality of touch pad electrodes TPE may transmit signals from the printed circuit board PCB and the flexible film COF to the touch line TL of a touch unit 150. The pad portion PAD may be exposed from the encapsulation layer 140 for connection with the flexible film COF. The pad portion PAD may be disposed on the outside of the encapsulation layer 140.

Wiring lines related to driving the display device 100, that is, image display, are disposed in the non-active area NA. For example, a plurality of low-potential power lines VSSL, a LOG (Line On Glass) line LOG, a plurality of high-potential power lines VDDL, a plurality of reference lines RL, and a plurality of data lines DL may be disposed in the non-active area NA.

The plurality of low-potential power lines VSSL is disposed in the non-active area NA. The plurality of low-potential power lines VSSL is lines for applying a low-potential power voltage to the plurality of sub-pixels SP. Some of the plurality of low-potential power lines VSSL extending from the pad portion PAD may extend in a form that encloses the periphery of the active area AA. In addition, other of the plurality of low-potential power lines VSSL extending from the pad portion PAD may be disposed to cover the data lines DL, thereby functioning as a protective film to suppress influences of the data lines DL on other lines.

The plurality of high-potential power lines VDDL is disposed in the non-active area NA. The plurality of high-potential power lines VDDL is wiring lines for applying a high-potential power voltage to the plurality of sub-pixels SP. The shorting-bar-shaped high-potential power line VDDL extending in a first direction D1 between the active area AA and the pad portion PAD is disposed. Moreover, the plurality of high-potential power lines VDDL extending in a second direction D2 from the pad portion PAD may be connected to the shorting-bar-shaped high-potential power line VDDL. In this case, a portion of the plurality of high-potential power lines VDDL extending in the second direction D2 from the pad portion PAD may be disposed between the plurality of low-potential power lines VSSL. Therefore, by forming the shorting bar-shaped high-potential power line VDDL that connects the plurality of high-potential power lines VDDL in the non-active area NA, the resistance deviation between the plurality of high-potential power lines VDDL can be reduced and the brightness uniformity can be improved.

In the non-active area NA, the reference line RL is disposed between the high-potential power line VDDL and the low-potential power line VSSL. A shorting-bar-shaped reference line RL extending in the first direction D1 between the active area AA and the pad portion PAD may be disposed, and a plurality of reference lines RL extending in a second direction D2 from the pad portion PAD may be connected to the shorting-bar-shaped reference line RL. At this time, the high-potential power line VDDL on the same layer as the reference line RL is disposed between the shorting-bar-shaped reference line RL and the reference line RL connected to the pad portion PAD. Accordingly, at the point where the reference line RL and the high-potential power line VDDL intersect each other, an auxiliary reference line RLa located on a different layer from the high-potential power line VDDL may be used to connect the shorting-bar-shaped reference line RL and the reference line RL connected to the pad portion PAD. Therefore, by forming the shorting-bar-shaped reference line RL that connects the plurality of reference lines RL in the non-active area NA, the resistance deviation between the plurality of reference lines RL can be reduced and the brightness uniformity can be improved.

In the non-active area NA, the LOG line LOG is disposed between the low-potential power line VSSL and the high-potential power line VDDL. The LOG line LOG is a wiring line for transmitting various signals to the gate driver GD. For example, the gate driver GD is mounted in the non-active area NA, and the LOG line LOG extends from the pad portion PAD to the gate driver GD to transmit various signals to the gate driver GD.

The plurality of data lines DL may be disposed to extend from the pad portion PAD. The plurality of data lines DL may be disposed to radially extend from the pad portion PAD. The plurality of data lines DL may extend from the pad portion PAD to the active area AA, thereby transmitting the data voltage Vdata to the plurality of sub-pixels SP of the active area AA.

Meanwhile, also referring to FIG. 17, a multiplexer circuit MUX, an electrostatic discharge protection circuit ESD, and a light inspection transistor AP may be further disposed between the shorting-bar-shaped reference line RL and the active area AA. The multiplexer circuit MUX is a circuit for distributing a signal to the plurality of wiring lines, and the output of each wiring line may be controlled using the multiplexer circuit MUX. The electrostatic discharge protection circuit ESD may protect the internal configuration of the display device 100 by discharging static electricity introduced from the outside. When checking whether the light-emitting diode 120 is turned on in the manufacturing process of the display device 100, a signal may be temporarily applied to the light-emitting diode 120 using the light inspection transistor AP.

Meanwhile, the wiring lines disposed between the pad portion PAD and the active area AA may also be referred to as link lines LL. That is, some of the wiring lines disposed in the non-active area NA may be defined as the link lines LL. For example, in order to distinguish between some of the data lines DL disposed in the active area AA and the remainder of the data lines DL disposed in the non-active area NA, the remainder of the data lines DL disposed in the non-active area NA may be referred to as data link lines LL. Similarly, some of the high-potential power lines VDDL, low-potential power lines VSSL, and reference lines RL disposed in the non-active area NA may also be referred to as high-potential power link lines LL, low-potential power link lines LL, reference link lines LL, or the like. Therefore, the following description will assume that the link lines LL define some of the wiring lines disposed in the non-active area NA.

Next, referring to FIG. 3 and FIG. 5A together, some configurations of the active area AA may be disposed to extend to the non-active area NA.

Meanwhile, in FIG. 5A, for convenience of explanation, the multi-buffer layer 111, the active buffer layer 112, the gate insulating layer 113, the first interlayer insulating layer 114, and the second interlayer insulating layer 115 are briefly represented as the insulating layer group IL. However, in reality, the multi-buffer layer 111, the active buffer layer 112, the gate insulating layer 113, the first interlayer insulating layer 114, and the second interlayer insulating layer 115 may be disposed between the substrate 110 and the low-potential power line VSSL.

The encapsulation layer 140 may be disposed to cover the entire active area AA and a portion of the non-active area NA extending from the active area AA. For example, the organic encapsulation layer 142 of the encapsulation layer 140 may be disposed from the active area AA to the area before a dam member DAM of the non-active area NA. Moreover, the first inorganic encapsulation layer 141 and the second inorganic encapsulation layer 143 may extend to an area outside the dam member DAM. The first inorganic encapsulation layer 141 and the second inorganic encapsulation layer 143 extending to the area outside the dam member DAM may be in contact with each other to seal the organic encapsulation layer 142.

Meanwhile, the second inorganic encapsulation layer 143 may be disposed to cover the entire first inorganic encapsulation layer 141 in at least a portion of the non-active area NA. The second inorganic encapsulation layer 143 may cover the edge of the first inorganic encapsulation layer 141, thereby minimizing or at least reducing lifting of the first inorganic encapsulation layer 141.

Organic insulating layers made of organic materials, such as the bank 117 and the planarization layer 116, are relatively vulnerable to moisture penetration compared to inorganic insulating layers. Therefore, the edges of the bank 117 and the planarization layer 116 may be disposed in the area inside the encapsulation layer 140. For example, the edges of the bank 117 and the planarization layer 116 may be disposed in the area inside the encapsulation layer 140 and may be disposed on the low-potential power line VSSL.

At least some of the plurality of insulating layers of the touch unit 150 may be disposed to extend from the active area AA to the non-active area NA. For example, the touch buffer layer 151, the touch insulation layer 152, or the like may extend to the outside of the encapsulation layer 140 and cover the edge of the encapsulation layer 140. For example, the touch passivation layer 153 may extend from the active area AA to the area inside the dam member DAM. For example, the touch protection layer 154 may extend from the active area AA to the area outside the dam member DAM. However, the touch protection layer 154 may be disposed only in the area overlapping the organic encapsulation layer 142, but is not limited thereto.

Moreover, a touch active area TAA where the touch electrode TE is disposed may be disposed from the active area AA to a part of the non-active area NA. In the touch active area TAA, the touch electrode TE and the bridge electrode BE are disposed to sense a touch input. The touch active area TAA may be formed to be larger than the active area AA.

A ground line GND and a pseudo line PS may be further disposed outside the touch active area TAA within the non-active area NA, that is, in the area where touch input is not sensed. The ground line GND and the pseudo line PS may reduce noise such as electromagnetic interference and improve touch performance, and a more detailed description thereof will be provided later.

A plurality of crack suppression patterns CSP is disposed in the non-active area NA. When manufacturing the display device 100, a configuration of the display device 100 is formed on a mother substrate, and the mother substrate may be cut into a plurality of pieces to manufacture the plurality of display devices 100. However, when cutting the mother substrate, cracks may occur in the substrate 110 or the configuration on the substrate 110 at the edge portion of the substrate 110 due to impact. The plurality of crack suppression patterns CSP are disposed along the edge of the substrate 110 and may suppress propagation of cracks into the display device 100. The plurality of crack suppression patterns CSP may be formed by patterning some of a plurality of insulating layers on the substrate 110. For example, the plurality of crack suppression patterns CSP may be formed of a multi-layer structure of an organic insulating layer and an inorganic insulating layer, but are not limited thereto.

The dam member DAM is disposed outside the organic encapsulation layer 142 in the non-active area NA. The dam member DAM is configured to suppress the overflow of the organic encapsulation layer 142 of the encapsulation layer 140. The dam member DAM may be disposed to enclose the active area AA. The dam member DAM may be disposed to enclose the organic encapsulation layer 142 of the encapsulation layer 140. The dam member DAM may be formed in a closed loop shape enclosing the active area AA and the organic encapsulation layer 142. The dam member DAM may be disposed on the low-potential power line VSSL while enclosing the organic encapsulation layer 142.

The dam member DAM may include a first dam member DAM1 and a second dam member DAM2. The first dam member DAM1 may be disposed between the second dam member DAM2 and the organic encapsulation layer 142. The first dam member DAM1 and the second dam member DAM2 may be formed from various insulating layers among the plurality of insulating layers on the substrate 110.

For example, referring to FIG. 6A, the first dam member DAM1 may be formed of a planarization layer pattern 116a made of the same material as the planarization layer 116 and a spacer pattern 130a made of the same material as the spacer 130. The second dam member DAM2 may be formed of the planarization layer pattern 116a, a bank pattern 117a made of the same material as the bank 117, and the spacer pattern 130a.

Referring to FIG. 6B, each of the first dam member DAM1 and the second dam member DAM2 may be formed of the planarization layer pattern 116a, the bank pattern 117a, and the spacer pattern 130a. The bank pattern 117a of the second dam member DAM2 may be disposed to cover a side surface of the planarization layer pattern 116a.

Referring to FIG. 6C, the first dam member DAM1 may be formed of the planarization layer pattern 116a and the spacer pattern 130a, and the second dam member DAM2 may be formed of the planarization layer pattern 116a, the bank pattern 117a, and the spacer pattern 130a. In this case, the spacer pattern 130a of the second dam member DAM2 may be formed of a plurality of slit patterns.

Therefore, the dam member DAM may be composed of a combination of various insulation layers as illustrated in FIGS. 6A to 6C.

Next, referring to FIG. 5B, a pad electrode PE is disposed in the non-active area NA. The pad electrode PE may transmit signals from the flexible film COF and the printed circuit board PCB to a link line LL and a wiring line. For example, the link line LL is disposed on an insulating layer group IL in the non-active area NA, and the pad electrode PE is disposed on the link line LL. The link line LL may transmit the signal from the pad electrode PE to the wiring line in the active area AA.

A plurality of gate conductive layers GAT may be disposed between the insulating layer groups IL in the non-active area NA. The plurality of gate conductive layers GAT may be included in various configuration, and for example, may configure the link line LL, gate driver GD, or the like.

A planarization layer dam 116P is disposed between the pad electrode PE and the dam member DAM in the non-active area NA. Since the planarization layer dam 116P is disposed to be spaced apart from the planarization layer 116 of the active area AA, it is possible to suppress the penetration of moisture into the active area AA through the planarization layer dam 116P. In addition, the planarization layer dam 116P may compensate for the step of the dam member DAM, thereby minimizing or at least reducing disconnection of the touch line TL or the like due to the step.

And referring to FIG. 2 and FIG. 7 together, the dam member DAM is configured in a closed loop shape enclosing the active area AA, so that at least some of the wiring lines extending from the pad portion PAD to the active area AA may intersect the dam member DAM. In particular, after the dam member DAM is formed, the encapsulation layer 140 and the touch unit 150 may be formed. Moreover, the wiring lines of the touch unit 150, for example, the link line LL functioning as the touch line TL, the pseudo line PS, and the ground line GND, may pass through the dam member DAM. In this case, the link line LL passing through the dam member DAM may be easily disconnected due to the step of the dam member DAM. Therefore, the width of the link line LL overlapping the dam member DAM may be formed wide to suppress the disconnection of the link line LL in the dam member DAM.

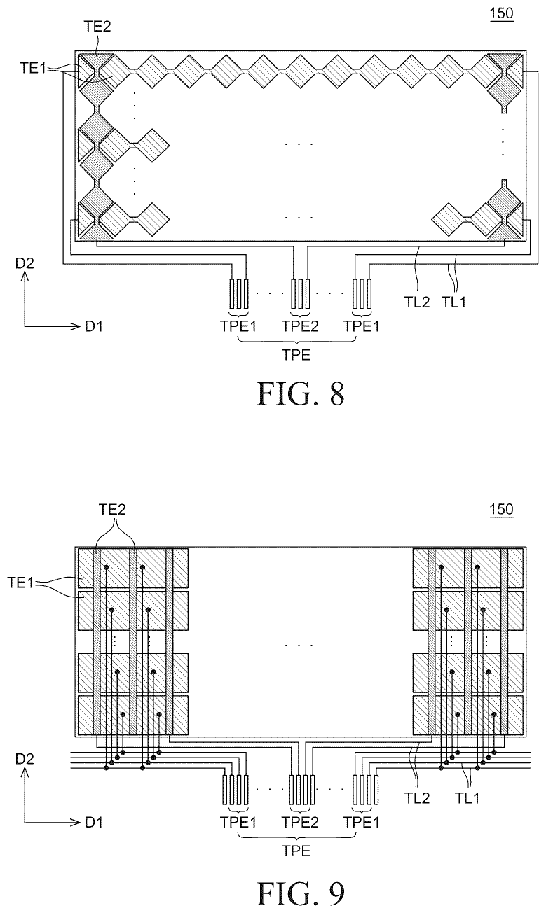

Hereinafter, the touch unit 150 of the display device 100 according to one or more embodiments of the present disclosure will be described in more detail with reference to FIGS. 8 to 23B.

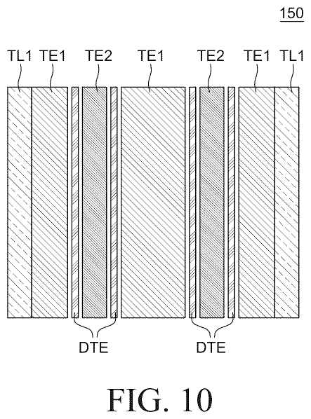

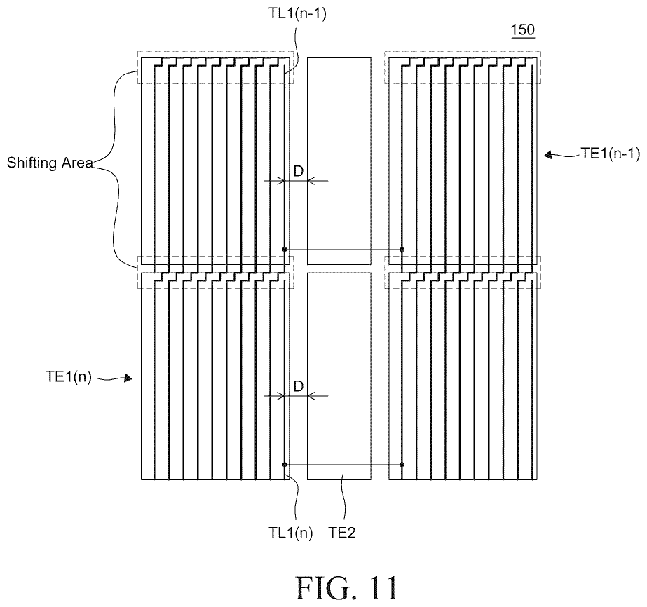

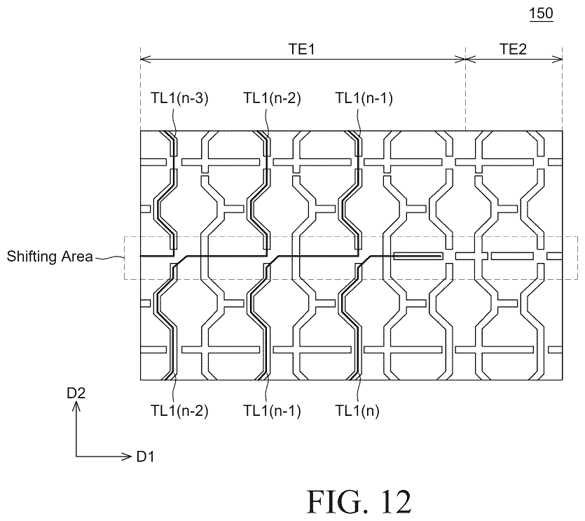

FIGS. 8 and 9 are schematic plan views of the touch unit of the display device according to one or more embodiments of the present disclosure. FIG. 10 is a schematic enlarged plan view of the touch unit of the display device according to one or more embodiments of the present disclosure. FIGS. 11 and 12 are schematic enlarged plan views of the touch unit of the display device according to one or more embodiments of the present disclosure.

First, the touch unit 150 may sense touch input using a mutual-capacitance method or a self-capacitance method. The mutual-capacitance method is a method of sensing touch input based on a change in capacitance between a touch driving electrode and a touch sensing electrode. The self-capacitance method is a method of sensing touch input based on a change in capacitance between an external input and a touch electrode.

Hereinafter, it will be explained assuming that the touch unit 150 of the display device 100 according to one or more embodiments of the present disclosure is the touch unit 150 that uses the mutual-capacitance method and the self-capacitance method in combination.

Referring to FIGS. 8 and 9, the touch unit 150 includes a plurality of touch lines TL and a plurality of touch electrodes TE. The plurality of touch lines TL includes a plurality of first touch lines TL1 and a plurality of second touch lines TL2, and the plurality of touch electrodes TE includes a plurality of first touch electrodes TE1 and a plurality of second touch electrodes TE2. In this case, as illustrated in FIGS. 8 and 9, the shape and disposition of the plurality of touch electrodes TE of the touch unit 150 and the connection structure of the touch electrodes TE and the touch lines TL may be configured in various ways.

For example, referring to FIG. 8, the plurality of first touch electrodes TE1 may be disposed in a matrix form with a predetermined interval. Each of the plurality of first touch electrodes TE1 may be formed in a diamond shape. In addition, among the plurality of first touch electrodes TE1, the first touch electrodes TE1 in the same line disposed along the first direction D1 may be connected to each other. For example, the first touch electrodes TE1 of the nth row may be electrically connected to each other to form a line of one first touch electrode TE1.

The plurality of second touch electrodes TE2 may be disposed in a matrix form with a predetermined interval. Each of the plurality of second touch electrodes TE2 may be formed in a diamond shape. The plurality of second touch electrodes TE2 may be disposed to be staggered with the plurality of first touch electrodes TE1. Among the plurality of second touch electrodes TE2, second touch electrodes TE2 in the same line disposed along the second direction D2 may be connected. For example, the second touch electrodes TE2 in the nth column may be electrically connected to each other to form a line of one second touch electrode TE2. Accordingly, the line of the first touch electrode TE1 and the line of the second touch electrode TE2 may intersect each other.

The plurality of first touch lines TL1 are electrically connected to the plurality of first touch electrodes TE1. The plurality of first touch lines TL1 is electrically connected to a first touch pad electrode TPE1 among the plurality of touch pad electrodes TPE, and may transmit the touch signal from the first touch pad electrode TPE1 to the plurality of first touch electrodes TE1. For example, the first touch lines TL1 may be connected to both ends of a line of one first touch electrode TE1 composed of the plurality of first touch electrodes TE1 disposed in the same row. By supplying a touch signal to both ends of the line of the first touch electrode TE1, a signal delay can be minimized or at least reduced.

The plurality of second touch lines TL2 is electrically connected to the plurality of second touch electrodes TE2. The plurality of second touch lines TL2 is electrically connected to a second touch pad electrode TPE2 among the plurality of touch pad electrodes TPE, and the second touch pad electrode TPE2 and the plurality of second touch electrodes TE2 can be electrically connected to each other. For example, the second touch line TL2 may be connected to one end of a line of the second touch electrode TE2 composed of the plurality of second touch electrodes TE2 disposed in the same row.

The touch unit 150 of FIG. 8 may be configured with a dual-feeding structure that simultaneously applies signals to both ends of the line of the touch electrodes TE. For example, as the size of the display device 100 increases, the length of the line of touch electrodes TE formed by the same line of touch electrodes TE increases, and signal transmission may be delayed depending on the position of the touch electrodes TE. Accordingly, in order to reduce the time deviation of transmitting and receiving a touch signal, one or more touch lines TL may be connected to the same line constituting the line of touch electrodes TE to minimize or at least reduce the signal delay.

Next, referring to FIG. 9, the plurality of first touch electrodes TE1 may be disposed in a matrix form with a predetermined interval. Each of the plurality of first touch electrodes TE1 may have a rectangular shape. Among the plurality of first touch electrodes TE1, the first touch electrodes TE1 of the same line disposed along the first direction D1 may receive a signal at the same time. For example, a plurality of first touch pad electrodes TPE1 is disposed in the non-active area NA, and an nth first touch line TL1 electrically connected to an nth first touch pad electrode TPE1 of the plurality of first touch pad electrodes TPE1 may be connected to the plurality of first touch electrodes TE1 disposed in the same line.

The plurality of second touch electrodes TE2 may be disposed between the plurality of first touch electrodes TE1. Each of the plurality of second touch electrodes TE2 may have a rectangular shape. For example, the plurality of first touch electrodes TE1 and the plurality of second touch electrodes TE2 may be disposed alternately in the first direction D1. The first touch electrodes TE1 and the second touch electrodes TE2 may be disposed in the same row, and the first touch electrodes TE1 and the second touch electrodes TE2 may be disposed in different columns. Among the plurality of second touch electrodes TE2, the second touch electrodes TE2 in the same line disposed along the second direction D2 may receive a signal at the same time. For example, the plurality of second touch pad electrodes TPE2 are disposed in the non-active area NA, and an nth second touch line TL2 electrically connected to an nth second touch pad electrode TPE2 among the plurality of second touch pad electrodes TPE2 may be connected to the plurality of second touch electrodes TE2 disposed on the same line.

The plurality of first touch lines TL1 is electrically connected to the plurality of first touch electrodes TE1. The plurality of first touch lines TL1 is electrically connected to the first touch pad electrode TPE1 among the plurality of touch pad electrodes TPE, and may transmit the touch signal from the first touch pad electrode TPE1 to the plurality of first touch electrodes TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE, and the second touch pad electrode TPE2 and the plurality of second touch electrodes TE2 may be electrically connected to each other.

Meanwhile, the touch unit 150 of FIG. 9 may be configured with a multi-feeding structure that simultaneously applies signals to the plurality of touch electrodes TE. For example, as the size of the display device 100 increases, the length of the line of touch electrodes TE formed by the touch electrodes TE of the same line may increase, and signal transmission may be delayed depending on the position of the touch electrodes TE. Accordingly, in order to reduce the time deviation of transmitting and receiving the touch signals, the touch line TL may be connected to each of the plurality of touch electrodes TE of the same line that constitutes the line of touch electrodes TE so that signals may be simultaneously applied. Accordingly, by connecting the plurality of touch lines TL one-to-one to each of the plurality of touch electrodes TE, the delay of the touch signal may be reduced, and the touch performance for the entire area of the display device 100 may be improved.

Moreover, the plurality of first touch electrodes TE1 may be touch driving electrodes, and the plurality of second touch electrodes TE2 may be touch sensing electrodes. Furthermore, the plurality of first touch lines TL1 may be touch driving lines, and the plurality of second touch lines TL2 may be touch sensing lines. In this case, the touch driver TD may transmit the touch driving signal to the first touch electrode TE1 through the first touch line TL1, and receive the touch sensing signal from the second touch electrode TE2 through the second touch line TL2.

However, the first touch electrode TE1 and the first touch line TL1 may each be the touch sensing electrode and the touch sensing line, and the second touch electrode TE2 and the second touch line TL2 may each be a touch driving electrode and a touch driving line, and embodiments of the present disclosure are not limited thereto.

Referring to FIG. 10, the plurality of touch electrodes TE may further include a plurality of dummy touch electrodes DTE. The dummy touch electrodes DTE may be disposed between the plurality of first touch electrodes TE1 and the plurality of second touch electrodes TE2. For example, the dummy touch electrode DTE may be disposed between the first touch electrodes TE1 and the second touch electrodes TE2. For example, the plurality of touch electrodes TE and the plurality of dummy touch electrodes DTE may be disposed at equal intervals. By disposing the dummy touch electrodes DTE, the distance between the first touch electrodes TE1 and the second touch electrodes TE2 may be secured, and the initial capacitance value between the first touch electrodes TE1 and the second touch electrodes TE2 may be reduced.

The touch input may be sensed by sensing the capacitance between the first touch electrode TE1 and the second touch electrode TE2. In this case, as the first touch electrode TE1 and the second touch electrode TE2 get closer, the initial capacitance value between the first touch electrode TE1 and the second touch electrode TE2 may increase, making it somewhat difficult to sense the capacitance change.

For example, when the first touch electrode TE1 and the second touch electrode TE2 are disposed at a first interval without the dummy touch electrode DTE, it can be assumed that the initial capacitance value between the first touch electrode TE1 and the second touch electrode TE2 is 100, and the amount of capacitance change upon touch input is 10. As a result, the capacitance value after touch input is 110. In this case, the difference between the initial capacitance value of 100 and the capacitance value after touch input of 110 is small, so it may be somewhat difficult to detect the touch.

Moreover, when the dummy touch electrode DTE is formed between the first touch electrode TE1 and the second touch electrode TE2, the gap between the first touch electrode TE1 and the second touch electrode TE2 increases. Accordingly, the initial capacitance value between the first touch electrode TE1 and the second touch electrode TE2 may decrease. For example, when the dummy touch electrode DTE is disposed between the first touch electrode TE1 and the second touch electrode TE2, the gap between the first touch electrode TE1 and the second touch electrode TE2 may increase by the first gap and the width of the dummy touch electrode DTE. Accordingly, the initial capacitance value may decrease to a value less than 100, for example, 50. When the amount of capacitance change during touch input is 10, the capacitance value after touch input is 60. In this case, the difference between the initial capacitance value of 50 and the capacitance value after touch input of 60 is relatively large, so that the touch can be easily detected.

Accordingly, by placing the dummy touch electrode DTE between the first touch electrode TE1 and the second touch electrode TE2, the gap between the first touch electrode TE1 and the second touch electrode TE2 may be secured, and the initial capacitance value between the first touch electrode TE1 and the second touch electrode TE2 may be lowered. Therefore, it is possible to improve the performance of the touch unit 150.

Next, referring to FIGS. 9 and 11, in the touch unit 150 of the multi-feeding structure, the plurality of first touch lines TL1 is disposed around the plurality of second touch electrodes TE2, and parasitic capacitance may be formed between the plurality of first touch lines TL1 and the second touch electrodes TE2. However, when the parasitic capacitance variation occurs between the plurality of first touch lines TL1 and the second touch electrodes TE2, the touch performance may be degraded. Therefore, in the display device 100 according to one or more embodiments of the present disclosure, a gap D between the second touch electrodes TE2 and the first touch lines TL1 may be uniformly formed, thereby minimizing or at least reducing the parasitic capacitance variation.

Specifically, the plurality of first touch lines TL1 may extend in the second direction D2 and be electrically connected to the plurality of first touch electrodes TE1 through contact holes. In this case, by shifting the first touch lines TL1 by one line in the first direction D1, a distance D between the contact holes through which the first touch electrodes TE1 and the first touch lines TL1 are connected and the second touch electrodes TE2, or the gap D may be configured to be constant.

First, an area between the plurality of first touch electrodes TE1 in the second direction D2, for example, an area between the first touch electrode TE1(n) of the nth row and the first touch electrode TE1(n−1) of the n−1th row and an area between the first touch electrode TE1(n) of the nth row and the first touch electrode TE1(n+1) of the n+1th row may be defined as a shifting area in which the first touch line TL1 shifts.

In the nth row, the nth first touch line TL1(n) may be disposed closest to the second touch electrode TE2. In the nth row, the contact hole through which the nth first touch line TL1(n) and the first touch electrode TE1(n) are connected and the second touch electrode TE2 may be disposed to be spaced apart from each other with the gap D.

In addition, the contact hole of the first touch electrode TE1(n) and the first touch line TL1(n) located on the right side of the second touch electrode TE2 and the contact hole of the first touch electrode TE1(n) and the first touch line TL1(n) located on the left side of the second touch electrode TE2 may be disposed symmetrically with respect to the second touch electrode TE2.

Moreover, the first touch line TL1(n) of the nth row for transmitting a signal to the first touch electrode TE1(n) of the nth row is electrically connected to the nth first touch electrode TE1(n). Accordingly, the first touch line TL1(n) is located only up to the shifting area between the nth first touch electrode TE1(n) and the n−1th first touch electrode TE1(n−1), and does not extend to the area of the n−1th first touch electrode TE1(n−1).

Moreover, the 1st first touch line TL1 to the (n−1)th first touch line TL1(n−1) may be shifted in the first direction D1 in the shifting area and extended again onto the (n−1)th first touch electrode TE1(n−1). In the (n−1)th row, the (n−1)th first touch line TL1(n−1) may be electrically connected to the first touch electrode TE1(n−1). Moreover, in the (n−1)th row, the contact hole through which the (n−1)th first touch line TL1(n−1) and the first touch electrode TE1(n−1) are connected and the second touch electrode TE2 may be disposed spaced apart from each other by the gap D.

Accordingly, by shifting the remaining first touch lines TL1 except for the nth first touch line TL1(n) connected to the nth first touch electrode TE1(n) in the shifting area and extending them in the second direction D2, the gap D between the contact hole connecting the first touch electrode TE1 and the first touch line TL1 and the second touch electrode TE2 may be configured to be the same.

Meanwhile, the plurality of touch electrodes TE may have a plate-shaped structure as illustrated in FIG. 11, but the plurality of touch electrodes TE may also be formed in a mesh structure as illustrated in FIG. 12. Even when the plurality of touch electrodes TE is formed in a mesh structure as illustrated in FIG. 12, a shifting area may be formed.

Referring to FIG. 12, the plurality of touch electrodes TE may be formed in a mesh structure, and openings of the mesh structure may overlap each of the plurality of sub-pixels SP. The metal of the plurality of touch electrodes TE may be disposed in an area between the plurality of sub-pixels SP. For example, the metal of the plurality of touch electrodes TE may be disposed in an octagonal shape in an area between the sub-pixels SP.

The first touch line TL1 may extend in a second direction D2 along the metal forming the first touch electrode TE1. The first touch line TL1, such as the touch lines TL1(n−3), TL1(n−2), and TL1(n−1), may be electrically connected to the metal of the first touch electrode TE1 through a contact hole in an area of a first gap with the second touch electrode TE2. In addition, the plurality of first touch lines TL1 may be shifted in the first direction D1 in a shifting area and then extend upward again.

Accordingly, the shifting area can be formed in the touch unit 150 of various structures, thereby forming a constant gap between the contact hole where the first touch electrode TE1 and the first touch line TL1 are connected and the second touch electrode TE2.

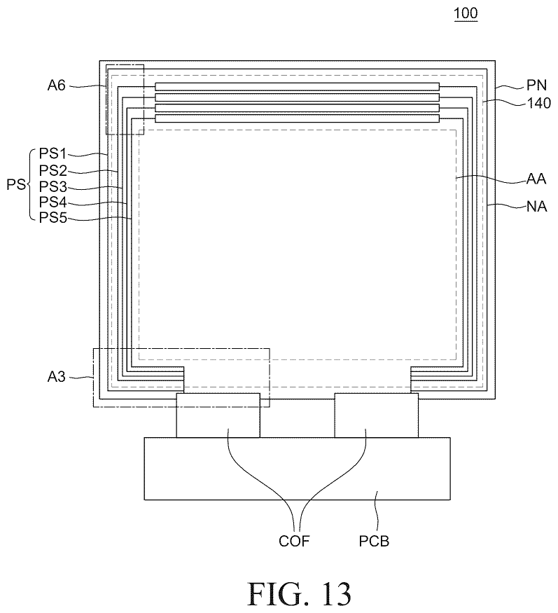

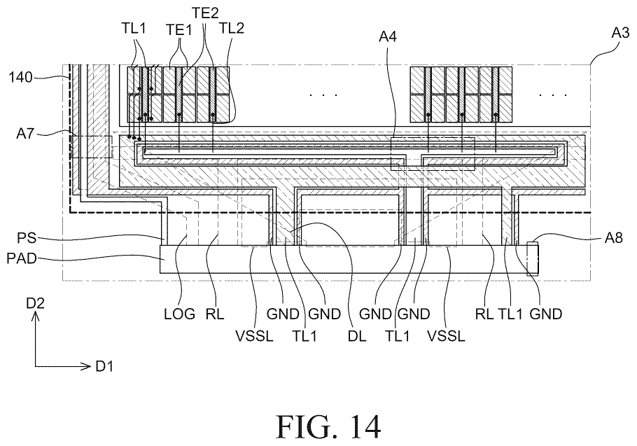

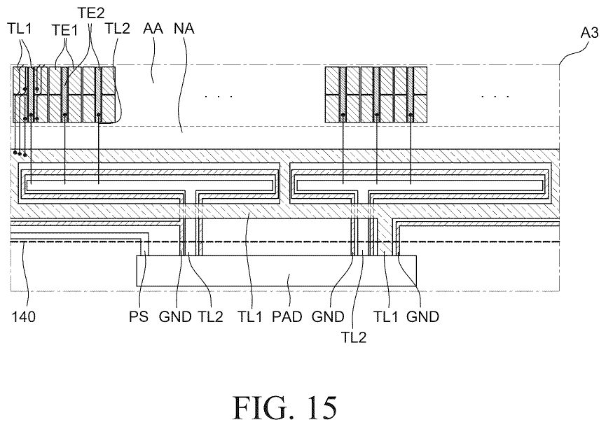

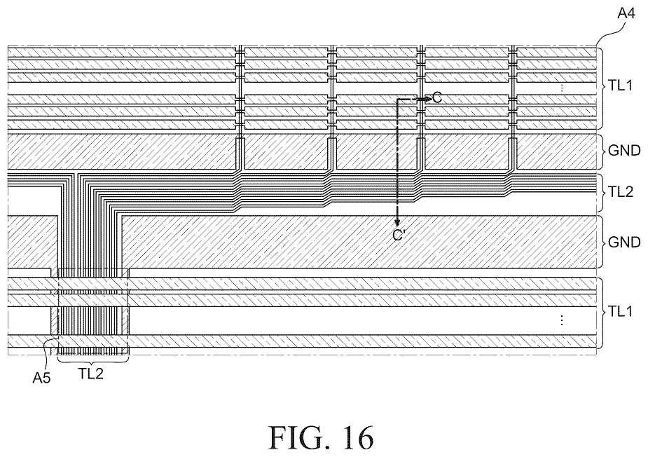

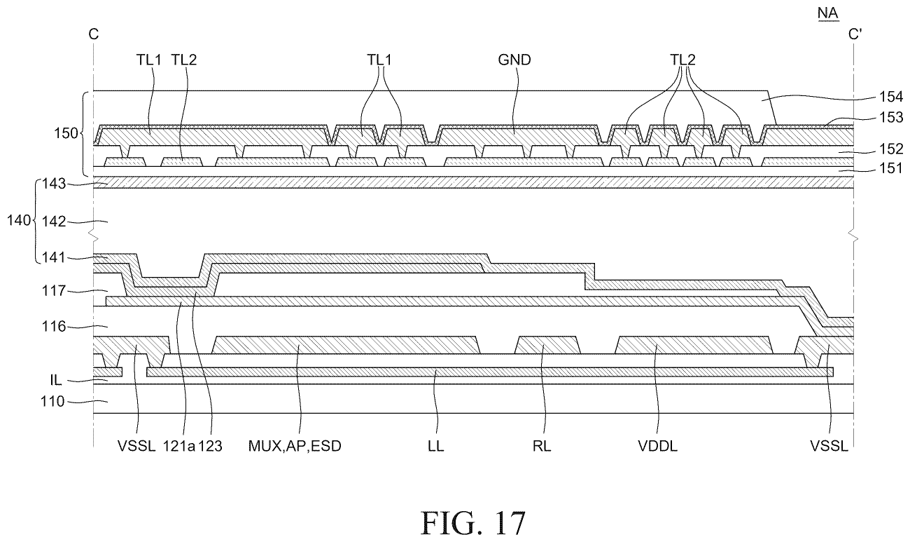

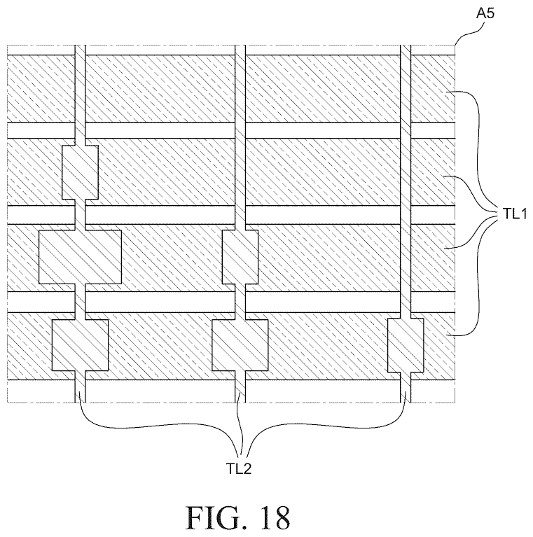

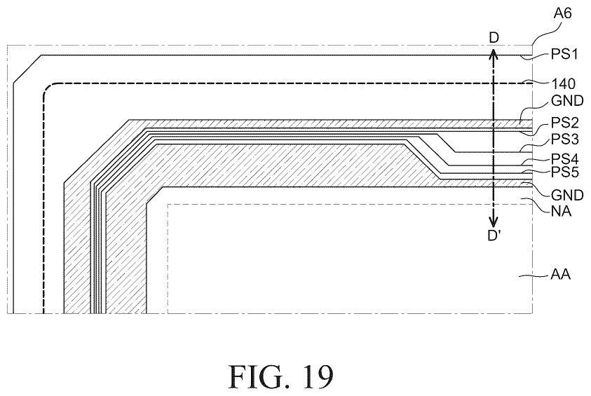

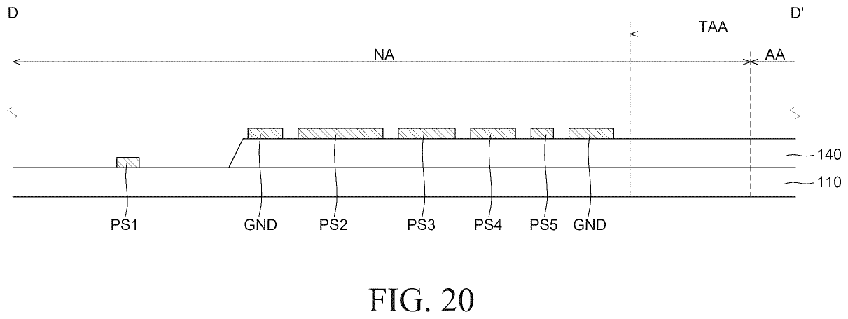

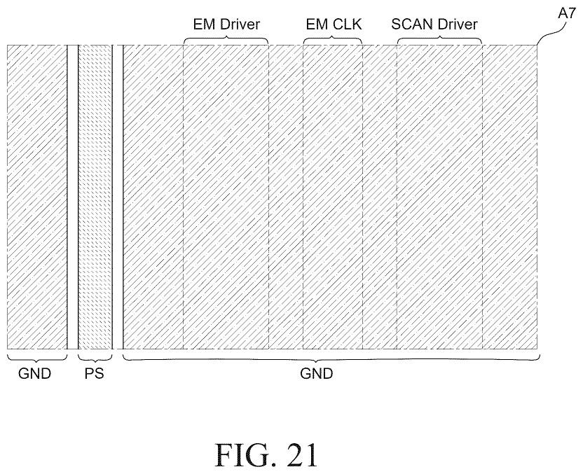

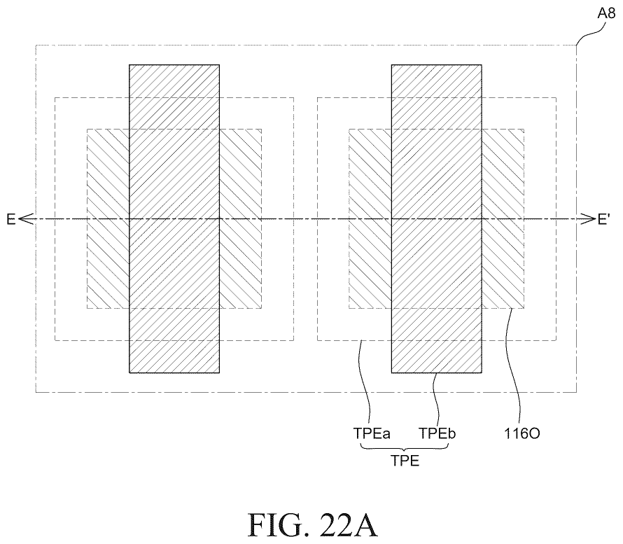

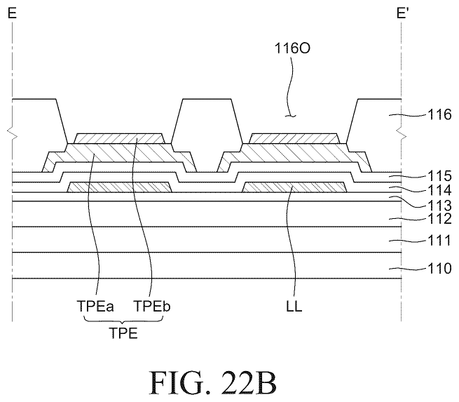

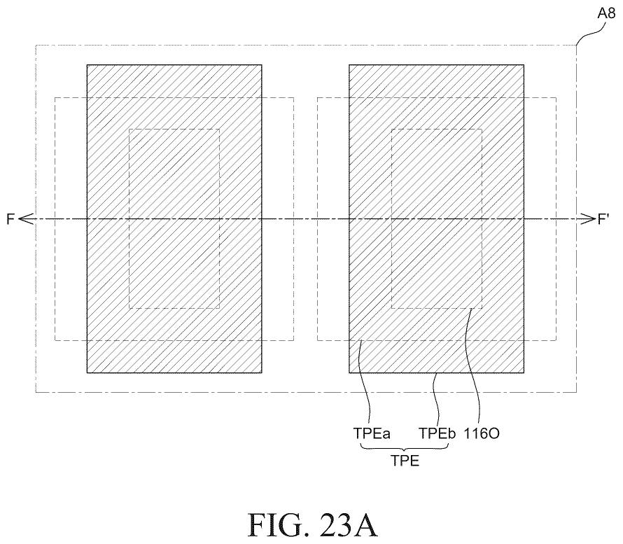

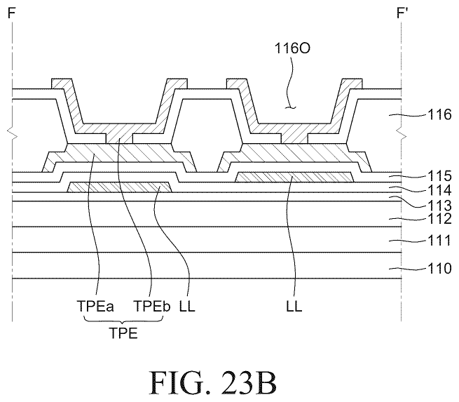

FIG. 13 is a schematic plan view of a display device according to one or more embodiments of the present disclosure. FIGS. 14 and 15 are enlarged plan views of an area A3 of FIG. 13. FIG. 16 is an enlarged plan view of an area A4 of FIG. 14. FIG. 17 is a cross-sectional view taken along line C-C′ of FIG. 16. FIG. 18 is an enlarged plan view of an area A5 of FIG. 16. FIG. 19 is an enlarged plan view of an area A6 of FIG. 13. FIG. 20 is a cross-sectional view taken along line D-D′ of FIG. 19. FIG. 21 is an enlarged plan view of an area A7 of FIG. 14. FIG. 2 2A is an enlarged plan view of an area A8 of FIG. 14. FIG. 22B is a cross-sectional view taken along line E-E′ of FIG. 22A. FIG. 23A is an enlarged plan view of an area A8 of FIG. 14. FIG. 23B is a cross-sectional view taken along line F-F′ of FIG. 23A. For convenience of explanation, in FIG. 14, among the plurality of wiring lines, the touch line TL, ground line GND, and pseudo line PS are drawn as solid lines, and the reference line RL, LOG line LOG, data line DL, and low-potential power line VSSL are drawn as dotted lines.

Referring to FIGS. 13 and 14 together, wiring lines related to the touch unit 150 are disposed in the non-active area NA. For example, the pseudo line PS, the plurality of touch lines TL, and the plurality of ground lines GND may be disposed in the non-active area NA.

Meanwhile, the display device 100 according to one or more embodiments of the present disclosure has a Touch On Encap (TOE) structure in which the touch unit 150 is disposed on the encapsulation layer 140, and most of the wiring lines related to the touch unit 150 may extend onto the encapsulation layer 140. Accordingly, the wiring lines related to driving the display device 100 illustrated in FIG. 4 and the wiring lines related to the touch unit 150 illustrated in FIG. 14 can be disposed on different layers, and at least some of the wiring lines may be disposed spaced apart from each other with the encapsulation layer 140 interposed therebetween.

For convenience of explanation, the wiring line related to driving the display device 100 and the wiring line related to the touch unit 150 among the wiring lines of the non-active area NA are each drawn as solid lines in FIGS. 4 and 14, but the wiring lines of the non-active area NA illustrated in FIGS. 4 and 14 are actually overlapping each other.

In addition, for convenience of explanation, each wiring line is represented as a single wiring line in FIGS. 4 and 14, but each wiring line may be composed of at least one group of wiring lines. For example, in FIG. 14, each of the touch lines TL and the pseudo lines PS is depicted as a single wiring line, but the touch lines TL and the pseudo lines PS may be composed of a group of a plurality of touch lines TL and a group of a plurality of pseudo lines PS.

Referring to FIG. 14, the plurality of first touch lines TL1 includes a portion extending in the second direction D2 from the touch pad electrode TPE of the pad portion PAD and another portion extending in the first direction D1 from the portion and disposed in a closed loop shape. For example, in the non-active area NA, the plurality of first touch lines TL1 may be formed of a vertical line portion extending from the pad portion PAD toward the encapsulation layer 140 and a horizontal line portion having a loop shape and having an empty space therein, which is disposed on the encapsulation layer 140. In addition, the plurality of first touch lines TL1 may branch from the horizontal line portions of the plurality of first touch lines TL1 in the second direction D2 and may be connected to the plurality of first touch electrodes TE1 of the active area AA.

In this case, at least one region in which the vertical line portions of the plurality of first touch lines TL1 are connected to the pad portion PAD may be disposed in the non-active area NA. For example, in FIG. 14, the vertical line portions of the plurality of first touch lines TL1 are connected to two regions of the pad portion PAD, and in FIG. 15, the vertical line portions of the plurality of first touch lines TL1 may be connected to one region of the pad portion PAD.

Additionally, the horizontal line portions of the plurality of first touch lines TL1 in the non-active area NA may form at least one loop. For example, in FIG. 14, the horizontal line portions of the plurality of first touch lines TL1 may form one loop, and in FIG. 15, the horizontal line portions of the plurality of first touch lines TL1 may form two loops.

The plurality of second touch lines TL2 include a portion extending in the second direction D2 from the touch pad electrode TPE of the pad portion PAD, and another portion extending in the first direction D1 from the portion and disposed in a bar shape. For example, in the non-active area NA, the plurality of second touch lines TL2 may be formed of a vertical line portion extending from the pad portion PAD toward the encapsulation layer 140 and a horizontal line portion disposed on the encapsulation layer 140 in a bar shape. The horizontal line portions of the plurality of second touch lines TL2 may be disposed in an empty space inside the horizontal line portions of the plurality of first touch lines TL1. That is, the horizontal line portions of the plurality of first touch lines TL1 in a loop shape may be disposed to enclose the horizontal line portions of the plurality of second touch lines TL2. Moreover, the plurality of second touch lines TL2 may be branched from the horizontal line portion of the plurality of second touch lines TL2 in the second direction D2 and connected to the plurality of second touch electrodes TE2 of the active area AA.

Meanwhile, at least a portion of the plurality of touch lines TL in the non-active area NA may be disposed outside the encapsulation layer 140. In this case, in the area where the encapsulation layer 140 is not disposed, the touch lines TL and the data lines DL are disposed relatively close together, and thus their signals may interfere with each other. Accordingly, a constant voltage line capable of shielding signals may be disposed at the intersection of the data lines DL and the touch lines TL in the area outside the encapsulation layer 140 to minimize or at least reduce signal interference.

For example, the low-potential power lines VSSL may be disposed between the plurality of first touch lines TL1 and the plurality of data lines DL in an area outside the encapsulation layer 140, and between the plurality of second touch lines TL2 and the plurality of data lines DL, thereby minimizing or at least reducing signal interference between the touch signal and the data voltage Vdata and improving touch sensing performance.

For example, the horizontal line portions of the plurality of second touch lines TL2 extending in the second direction D2 in the non-active area NA may be disposed to overlap the shorting-bar-shaped reference line RL. Accordingly, the shorting-bar-shaped reference line RL may be disposed between the plurality of data lines DL and the horizontal line portions of the plurality of second touch lines TL2, thereby functioning as a protective film that minimizes or at least reduces signal interference between the plurality of data lines DL and the second touch lines TL2.

Next, referring to FIG. 14, the plurality of pseudo lines PS is disposed in the non-active area NA. The plurality of pseudo lines PS may be disposed to enclose the active area AA. When the display device 100 transmits and receives a wireless signal with another device, electromagnetic interference with the touch signal may occur, and the transmission and reception performance of the wireless signal and the touch sensing performance may deteriorate. The plurality of pseudo lines PS is wiring lines for canceling the electromagnetic interference between the wireless signal and the touch signal, and the electromagnetic interference may be canceled by supplying a pseudo touch signal of an opposite phase to the touch driving signal to the plurality of pseudo lines PS.

Referring to FIG. 14, the plurality of ground lines GND is disposed between the plurality of touch lines TL and the plurality of pseudo lines PS. By discharging noise charges or the like flowing into the display panel PN to the ground voltage of the ground lines GND, the touch lines TL and pseudo lines PS may be protected, and touch sensing performance may be improved.

Some of the plurality of ground lines GND may extend along the plurality of touch lines TL and may be disposed adjacent to each of the plurality of touch lines TL. For example, some of the plurality of ground lines GND may be disposed along vertical line portions and horizontal line portions of the plurality of first touch lines TL1, and other some of the plurality of ground lines GND may be disposed along vertical line portions and horizontal line portions of the plurality of second touch lines TL2. For example, another some of the plurality of ground lines GND may be disposed between horizontal line portions of the plurality of first touch lines TL1 in a loop shape and horizontal line portions of the plurality of second touch lines TL2 and may be formed in a loop shape. For example, other some of the plurality of ground lines GND may extend along the plurality of pseudo lines PS and may be disposed adjacent to each of the plurality of pseudo lines PS.

Moreover, referring to FIGS. 13, 14, 19 and 20 together, some of the plurality of pseudo lines PS and the plurality of ground lines GND in the non-active area NA may be disposed on the encapsulation layer 140, and the remainder may be disposed in an area outside the encapsulation layer 140. For example, the plurality of pseudo lines PS may include a first pseudo line PS1, a second pseudo line PS2, a third pseudo line PS3, a fourth pseudo line PS4, and a fifth pseudo line PS5. Among the plurality of pseudo lines PS, the first pseudo line PS1 may be disposed in an area outside the encapsulation layer 140, and the second pseudo line PS2, the third pseudo line PS3, the fourth pseudo line PS4, and the fifth pseudo line PS5 may be disposed on the encapsulation layer 140.

The ground line GND may be disposed on both sides of the second pseudo line PS2, the third pseudo line PS3, the fourth pseudo line PS4, and the fifth pseudo line PS5 on the encapsulation layer 140. The ground line GND between the first pseudo line PS1 and the second pseudo line PS2 may alleviate electromagnetic interference between configurations disposed below a plurality of pseudo lines PS, for example, the gate driver GD (referring to FIG. 5A) and the plurality of pseudo lines PS. The ground line GND between the fifth pseudo line PS5 and the active area AA may function as a protective film that inhibits the configurations of the active area AA and the pseudo lines PS from being influenced by each other, thereby alleviating electromagnetic interference.

Moreover, one or more pseudo lines PS may be disposed in an area outside the encapsulation layer 140, and a ground line GND may be further disposed outside the pseudo line PS. For example, referring to FIG. 5A, one or more pseudo lines PS may be disposed in an area outside the encapsulation layer 140, and the ground line GND may be disposed in an area outside the pseudo line PS. Moreover, the ground line GND disposed at the outermost side may discharge static electricity to protect other components inside the display device 100, including the pseudo line PS.

Meanwhile, in FIG. 13, FIG. 19, and FIG. 20, it is illustrated that there are five pseudo lines PS1 to PS5 and only the first pseudo line PS1 is disposed outside the encapsulation layer 140. However, the disposition and number of the pseudo lines PS may be changed in consideration of the size of the non-active area NA, the formation area of the encapsulation layer 140, or the like, and embodiments of the present disclosure are not limited thereto.

Next, referring to FIG. 16, in the upper region of the first non-active area NA, the widths of the plurality of first touch lines TL1 may be narrowed at points where the plurality of first touch lines TL1 and the plurality of second touch lines TL2 intersect. The width of a portion of the plurality of first touch lines TL1 that intersects the plurality of second touch lines TL2 may be narrower than the width of another portion that does not intersect the plurality of second touch lines TL2. By configuring the widths of the plurality of first touch lines TL1 to be narrow at points where the plurality of first touch lines TL1 and the plurality of second touch lines TL2 intersect, interference between the plurality of first touch lines TL1 and the plurality of second touch lines TL2 can be minimized or at least reduced.

Referring to FIGS. 16 and 17 together, the first touch line TL1, the second touch line TL2, and the ground line GND may be formed as a double wiring line structure. For example, each of the first touch line TL1, the second touch line TL2, and the ground line GND may be formed as a bilayer structure of the bridge metal BM on the touch buffer layer 151 and the sensor metal SM on the touch insulation layer 152. In addition, the bridge metal BM and the sensor metal SM of each of the first touch line TL1, the second touch line TL2, and the ground line GND may be connected to each other through the contact hole of the touch insulation layer 152.

In this case, at the intersection of the first touch line TL1 and the second touch line TL2, the first touch line TL1 and the second touch line TL2 may use different metals. For example, at the intersection of the first touch line TL1 and the second touch line TL2, the first touch line TL1 may be composed only of a bridge metal BM on the touch insulation layer 152, and the second touch line TL2 may be composed only of a sensor metal SM between the touch buffer layer 151 and the touch insulation layer 152.

Meanwhile, the cathode 123 may be electrically connected to the low-potential power line VSSL using an anode pattern 121a in the non-active area NA. For example, the anode pattern 121a of the same material as the anode 121 may be connected to the low-potential power line VSSL in the non-active area NA. In addition, an opening in which the anode pattern 121a is exposed may be formed in the bank 117, and the cathode 123 may be extended from the active area AA to the opening. Therefore, the cathode 123, the anode pattern 121a, and the low-potential power line VSSL may be electrically connected to each other.

In addition, in the non-active area NA, the multiplexer circuit MUX, the light inspection transistor AP, the electrostatic discharge protection circuit ESD, and the like are disposed below the touch unit 150. Moreover, the shorting-bar-shaped reference line RL, the high-potential power line VDDL, and the low-potential power line VSSL, or the like described in FIG. 4 may also be disposed.

Next, referring to FIG. 18, in the area below the first non-active area NA, the width of the plurality of second touch lines TL2 may be varied at a point where the plurality of first touch lines TL1 and the plurality of second touch lines TL2 intersect, thereby compensating for the capacitance variation of each of the plurality of touch lines TL.

For example, each of the plurality of touch lines TL may have a different length depending on the shape of the display device 100, the position of the touch electrode TE, or the like. For example, when the display device 100 has a non-rectangular shape, the lengths of the plurality of touch lines TL may vary by region. When the lengths of the plurality of touch lines TL are different, the capacitance variation may occur depending on the difference in the overlapping size between the plurality of touch lines TL. For example, when the lengths of the plurality of second touch lines TL2 are different, the overlapping size between each of the plurality of second touch lines TL2 and the first touch line TL1 is different, and the capacitance value between each of the plurality of second touch lines TL2 and the first touch line TL1 may also vary. Accordingly, by varying the width of the second touch line TL2, the overlapping size between the first touch line TL1 and the second touch line TL2 and the capacitance value resulting therefrom may be controlled.

For example, when the second touch line TL2 on the left among the three second touch lines TL2 has a relatively short length, the width of the second touch line TL2 may be widened in three areas among the intersection areas of the second touch line TL2 on the left and the plurality of first touch lines TL1. Therefore, it is possible to increase the overlapping size of the first touch line TL1 and the second touch line TL2 and increase the capacitance. For example, when the second touch line TL2 on the right among the three second touch lines TL2 has a relatively long length, the width of the second touch line TL2 may be widened in only one area among the intersection areas of the second touch line TL2 and the plurality of first touch lines TL1. Further, the width of the second touch line TL2 may vary in the intersection areas with different first touch lines TL1. Therefore, by varying the width of the second touch line TL2 at the intersection points of the first touch lines TL1 and the second touch lines TL2, the capacitance variation of each of the plurality of touch lines TL can be reduced.

Meanwhile, referring to FIG. 21 and FIG. 5A together, the area where the LOG line LOG is disposed is the area where the gate driver GD is disposed, and the scan signal driver SCAN Driver or the light emission signal driver EM Driver that constitutes the gate driver GD may be disposed together. For example, in the non-active area NA, the light emission signal driver EM Driver and the scan signal driver SCAN Driver may be disposed, and the LOG line LOG, for example, an emission clock signal line EM CLK, may be disposed between the light emission signal driver EM Driver and the scan signal driver SCAN Driver.

In this case, the plurality of pseudo lines PS may be disposed in the non-active area NA and may overlap the gate driver GD (referring to FIG. 5A), and accordingly, electromagnetic interference or the like may occur between the plurality of pseudo lines PS and the gate driver GD. Accordingly, the width of the ground line GND disposed adjacent to the plurality of pseudo lines PS and overlapping the gate driver GD may be formed wider. For example, the ground line GND may be disposed to cover all of the scan signal driver SCAN Driver and the light emission signal driver EM Driver of the gate driver GD and the LOG line LOG. For example, the width of the ground line GND overlapping the gate driver GD may be wider than the width of the gate driver GD. For example, the width of the ground line GND overlapping the gate driver GD is greater than the sum of the width of the scan signal driver SCAN Driver and the width of the light emission signal driver EM Driver. The ground line GND may function as a protective film that shields the signal of the gate driver GD from affecting the plurality of pseudo lines PS. Therefore, by forming the ground line GND overlapping the gate driver GD with a wide width, which is disposed on one side of the plurality of pseudo lines PS, the electromagnetic interference between the gate driver GD and the pseudo lines PS can be minimized or at least reduced.

Next, referring to FIGS. 22A and 23B, the pad portion PAD may further include a plurality of touch pad electrodes TPE to which wiring lines related to driving the display panel PN are connected, in addition to a plurality of pad electrodes PE to which wiring lines related to the touch unit 150 are connected. The plurality of touch pad electrodes TPE may be formed in various structures.

For example, referring to FIGS. 22A and 22B, the touch pad electrode TPE is disposed on the pad portion PAD. The flexible film COF may be bonded on the touch pad electrode TPE to connect the touch driver TD and the touch unit 150. The touch pad electrode TPE includes a first pad conductive layer TPEa and a second pad conductive layer TPEb on the first pad conductive layer TPEa.

The first pad conductive layer TPEa is disposed between the second interlayer insulating layer 115 and the planarization layer 116, and the planarization layer 116 includes an opening 116O through which the first pad conductive layer TPEa is exposed. The opening 116O of the planarization layer 116 may have a smaller size than the first pad conductive layer TPEa.

The second pad conductive layer TPEb is disposed on the planarization layer 116. The second pad conductive layer TPEb may be in contact with the first pad conductive layer TPEa at the opening 116O of the planarization layer 116. The second pad conductive layer TPEb may be formed using the same material and the same process as the conductive layer of the touch electrode TE. The second pad conductive layer TPEb may have a smaller size than the opening 116O of the planarization layer 116.

Referring to FIGS. 23A and 23B, the touch pad electrode TPE includes the first pad conductive layer TPEa and the second pad conductive layer TPEb on the first pad conductive layer TPEa.

The first pad conductive layer TPEa is disposed between the second interlayer insulating layer 115 and the planarization layer 116, and the planarization layer 116 includes the opening 116O through which the first pad conductive layer TPEa is exposed. The opening 116O of the planarization layer 116 may have a smaller size than the first pad conductive layer TPEa.

At least one of the insulating layers of the touch unit 150 is disposed on the planarization layer 116, and the second pad conductive layer TPEb is disposed on the insulating layer of the touch unit 150. For example, the touch buffer layer 151 may be disposed between the planarization layer 116 and the second pad conductive layer TPEb. The touch buffer layer 151 may overlap the opening 116O of the planarization layer 116 and have an opening that is smaller in size than the opening 116O of the planarization layer 116. The second pad conductive layer TPEb may be in contact with the first pad conductive layer TPEa through the opening of the touch buffer layer 151 and the opening 116O of the planarization layer 116.

However, the touch insulation layer 152 may be additionally disposed in addition to the touch buffer layer 151 between the planarization layer 116 and the second pad conductive layer TPEb, or the touch insulation layer 152 may be disposed instead of the touch buffer layer 151, but the present disclosure is not limited thereto.

In this case, the plurality of link lines LL may be disposed under the plurality of touch pad electrodes TPE. The plurality of link lines LL may be composed of various layers of conductive layers. For example, referring to FIG. 22B, the plurality of link lines LL may be disposed between the gate insulating layer 113 and the first interlayer insulating layer 114, and may be connected to another touch pad electrode TPE or another pad electrode PE. For another example, referring to FIG. 23B, some of the plurality of link lines LL may be disposed between the gate insulating layer 113 and the first interlayer insulating layer 114, and other some of the plurality of link lines LL may be disposed between the first interlayer insulating layer 114 and the second interlayer insulating layer 115.

Accordingly, in the display device 100 according to one or more embodiments of the present disclosure, the touch unit 150 is disposed on the encapsulation layer 140, and various configurations may be disposed to improve the performance of the touch unit 150. For example, the shifting area in which the plurality of first touch lines TL1 are shifted and extended between the plurality of first touch electrodes TE1 may be formed. Therefore, the gap between the contact hole through which the first touch lines TL1 and the first touch electrodes TE1 are connected and the second touch electrodes TE2 may be formed to be constant, and the parasitic capacitance between the first touch lines TL1 and the second touch electrodes TE2 may be configured to be uniform. For example, the delay of the touch signal may be minimized or at least reduced by applying a dual feeding structure that connects one or more touch lines TL to the line of one touch electrode TE or a multi-feeding structure that connects the touch line TL to each of the touch electrodes TE.

For another example, the plurality of pseudo lines PS to which signals having opposite phases to those of touch lines TL are applied may be disposed in the non-active area NA to suppress electromagnetic interference that occurs when transmitting and receiving wireless signals. For example, the ground line GND may be disposed around the plurality of pseudo lines PS to minimize or at least reduce interference between signals of the plurality of pseudo lines PS and the gate driver GD, and to protect other components of the display device 100 including the plurality of pseudo lines PS from static electricity. For example, in the non-active area NA, various lines for driving the display panel PN and various wiring lines for driving the touch unit 150 may overlap each other. Accordingly, the data lines DL and touch lines TL may overlap each other, and the low-potential power line VSSL or the reference line RL, which functions as a shielding film, may be disposed between the touch lines TL and the data lines DL to inhibit their signals from interfering with each other.

Therefore, in the display device 100 according to one or more embodiments of the present disclosure, by applying the above configuration, the capacitance variation of the touch electrode TE and the touch line TL, signal interference or electromagnetic interference between the touch unit 150 and other configurations can be reduced, thereby improving the touch sensing performance of the touch unit 150.

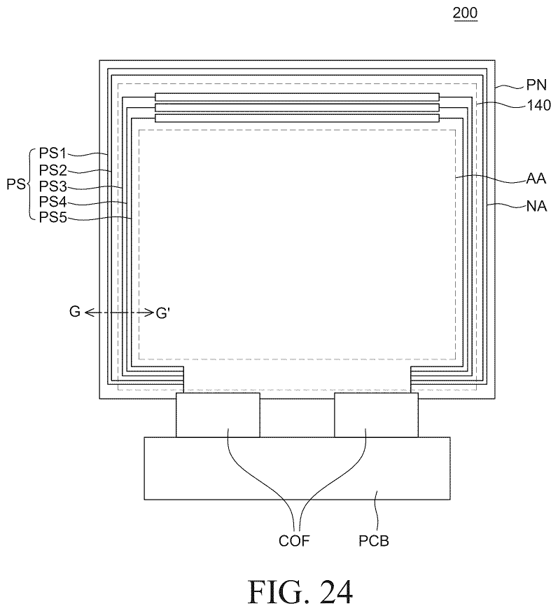

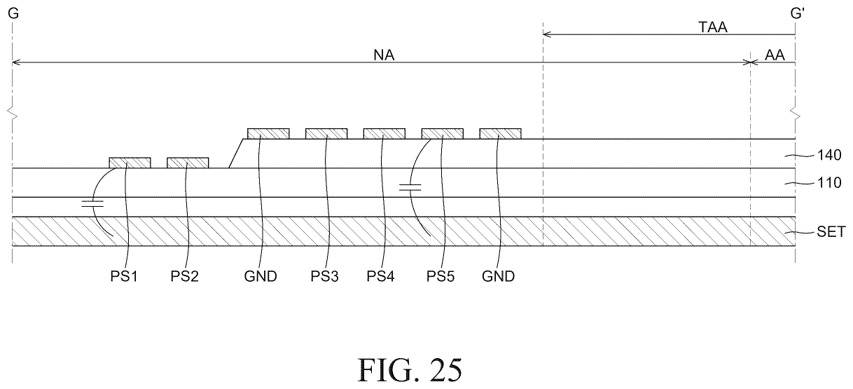

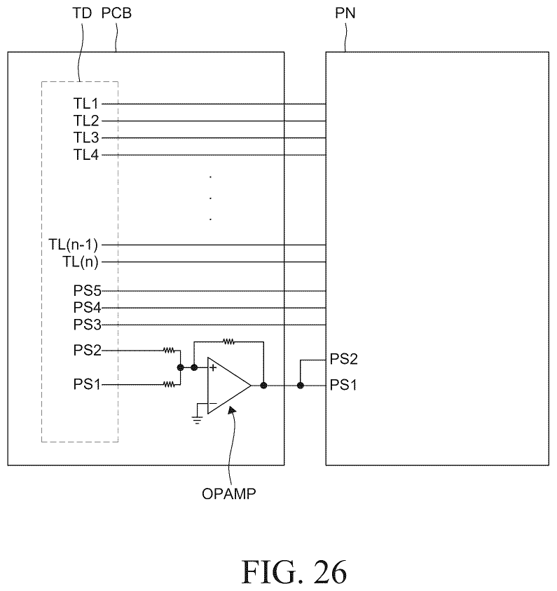

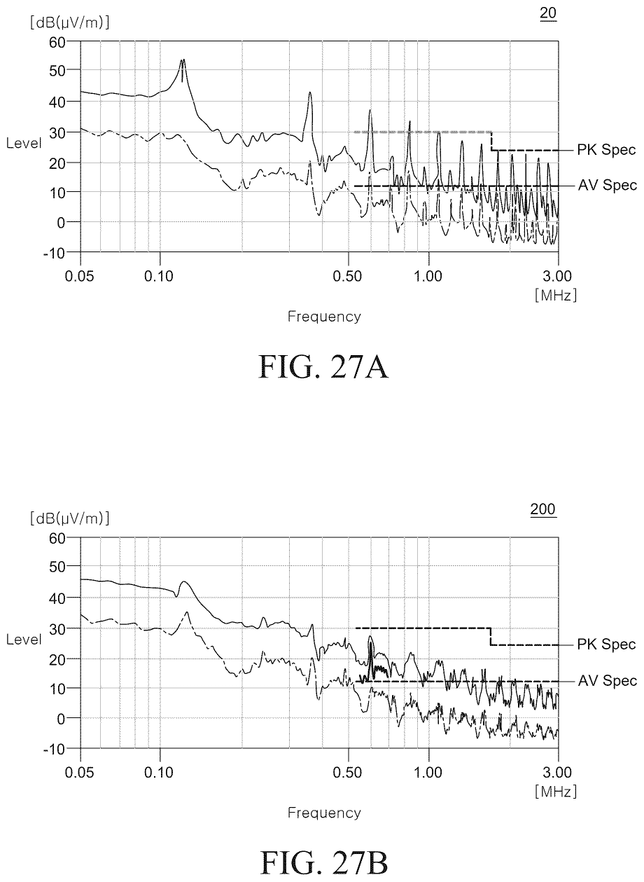

FIG. 24 is a schematic plan view of a display device according to one or more other embodiments of the present disclosure. FIG. 25 is a cross-sectional view taken along line G-G′ of FIG. 24. FIG. 26 is a schematic configuration diagram of a display device according to one or more other embodiments of the present disclosure. FIG. 27A is a graph measuring noise of a touch signal due to electromagnetic interference of a display device according to a comparative example. FIG. 27B is a graph measuring noise of a touch signal due to electromagnetic interference of a display device according to one or more other embodiments of the present disclosure. A display device 200 of FIGS. 24 to 26 is substantially the same as the display devices 100 of FIGS. 1 to 23B except that the disposition of the pseudo line PS is different and an amplifier OPAMP is further included. Therefore, duplicate descriptions thereof will be omitted.

Referring to FIGS. 24 and 25, the display device 200 according to one or more other embodiments of the present disclosure includes a plurality of pseudo lines PS disposed in a non-active area NA. For example, the plurality of pseudo lines PS may include a first pseudo line PS1, a second pseudo line PS2, a third pseudo line PS3, a fourth pseudo line PS4, and a fifth pseudo line PS5.

Moreover, some of the plurality of pseudo lines PS may be disposed on the encapsulation layer 140, and the remainder may be disposed in an area outside the encapsulation layer 140. Since there is not enough space on the encapsulation layer 140 to dispose all of the plurality of pseudo lines PS, some of the pseudo lines PS may be disposed outside the encapsulation layer 140. For example, the first pseudo line PS1 and the second pseudo line PS2 may be disposed outside the encapsulation layer 140, and the third pseudo line PS3, the fourth pseudo line PS4, and the fifth pseudo line PS5 may be disposed on the encapsulation layer 140.

A set cover SET is disposed to enclose the outer surface of the display device 200. The set cover SET may be disposed to cover the remaining surfaces of the display device 200 except for the surface on which an image is displayed. The set cover SET may be combined with the display device 200 to produce the display device 200. In this case, the set cover SET may form a ground surface in a state of being ground.

Meanwhile, the signal radiation amount of the pseudo line PS may be increased to reduce touch signal noise. The width of the pseudo line PS may increase in order to increase the signal radiation amount. However, as the width of the pseudo line PS increases, coupling between the pseudo line PS and the set cover SET in the ground state is more likely to occur. The radiation amount of the pseudo line PS is weakened by the capacitance between the pseudo line PS and the ground, making it difficult to improve the touch signal noise.

In this case, among the plurality of pseudo lines PS, the third pseudo line PS3, the fourth pseudo line PS4, and the fifth pseudo line PS5 located on the encapsulation layer 140 are disposed on the encapsulation layer 140 and are disposed relatively far from the set cover SET. Therefore, the coupling between the pseudo line PS and the set cover SET may be relatively weak. However, among the plurality of pseudo lines PS, the first pseudo line PS1 and the second pseudo line PS2 are disposed in the area outside the encapsulation layer 140, and are disposed relatively close to the set cover SET. Therefore, the coupling between the pseudo line PS and the set cover SET is strongly generated, and thus, the radiation amount may be significantly reduced.

Referring to FIG. 26, in the display device 200 according to one or more other embodiments of the present disclosure, the amplifier OPAMP is connected to the first pseudo line PS1 and the second pseudo line PS2 disposed below the encapsulation layer 140, so as to amplify a signal transmitted to the first pseudo line PS1 and the second pseudo line PS2. The amplifier OPAMP is connected to the first pseudo line PS1 and the second pseudo line PS2 disposed relatively close to the set cover SET among the plurality of pseudo lines PS, so as to amplify a signal and increase the radiation amount of the first pseudo line PS1 and the second pseudo line PS2.

A touch integrated circuit (IC) constituting the touch driver TD is disposed on the printed circuit board PCB. As shown in FIG. 26, the plurality of pseudo lines PS and the plurality of touch lines TL may be connected between the touch driver TD and the display panel PN. The amplifier OPAMP may be disposed on the printed circuit board PCB and connected to the first pseudo line PS1 and the second pseudo line PS2. The first pseudo line PS1 and the second pseudo line PS2 extended from the touch driver TD may connected to input terminals of the amplifier OPAMP, and an output terminal of the amplifier OPAMP may be connected to the first pseudo line PS1 and the second pseudo line PS2 of the display panel PN. Therefore, the amplifier OPAMP may amplify a pseudo signal from the touch driver TD and output the amplified pseudo signal to the first pseudo line PS1 and the second pseudo line PS2 of the display panel PN.

FIGS. 27A and 27B are graphs measuring noise of a touch signal due to electromagnetic interference.

Referring to FIG. 27A, a display device 20 according to the comparative example is identical to the display device 200 of FIGS. 24 to 26 in all other configurations except that the display device 20 does not include the amplifier OPAMP. In the display device 20 according to the comparative example, the signal radiation amount of the first pseudo line PS1 and the second pseudo line PS2 is reduced due to the coupling of the first pseudo line PS1 and the second pseudo line PS2 with the set cover SET. Accordingly, it can be confirmed that the peak of the noise of the touch signal due to electromagnetic interference exceeds a targeted peak specification PK Spec, and the average value of the noise also exceeds a targeted average specification AV Spec.

Referring to FIG. 27B, the display device 200 according to one or more other embodiments of the present disclosure may include the amplifier OPAMP to compensate for the decrease in the signal radiation amount of the first pseudo line PS1 and the second pseudo line PS2 due to coupling with the set cover SET. The signal radiation amount of the first pseudo line PS1 and the second pseudo line PS2 may be increased by the amplifier OPAMP. Accordingly, it may be confirmed that the peak of the noise of the touch signal is formed within the range of the target peak specification PK Spec, and the average value of the noise is also located within an average specification AV Spec range.

Accordingly, in a display device 200 according to one or more other embodiments of the present disclosure, the amplifier OPAMP is connected to the first pseudo line PS1 and the second pseudo line PS2, which are disposed outside the encapsulation layer 140 and are strongly affected by coupling with the set cover SET. Accordingly, it is possible to compensate for the reduction in the signal radiation amount of the first pseudo line PS1 and the second pseudo line PS2, and to reduce the noise of the touch signal due to electromagnetic interference.

The embodiments of the present disclosure can also be described as follows:
According to one or more embodiments of the present disclosure, there is provided a display device. The display device includes a substrate including an active area and a non-active area. The display device further includes an encapsulation layer disposed on the substrate. The display device further includes a plurality of pseudo lines disposed in the non-active area. The display device further includes an amplifier connected to some of the plurality of pseudo lines. Some of the plurality of pseudo lines are disposed outside the encapsulation layer in the non-active area, and the remainder of the plurality of pseudo lines are disposed on the encapsulation layer in the non-active area.

The plurality of pseudo lines may be disposed to enclose the active area.

The plurality of pseudo lines may include: a first pseudo line disposed outside the encapsulation layer, a second pseudo line disposed outside the encapsulation layer, a third pseudo line disposed on the encapsulation layer, a fourth pseudo line disposed on the encapsulation layer, and a fifth pseudo line disposed on the encapsulation layer. The amplifier may be connected to the first pseudo line and the second pseudo line.

The display device may further include a set cover disposed under the substrate. The set cover may be coupled to at least some of the plurality of pseudo lines.

The display device may further include: a plurality of flexible films connected to the substrate, and a printed circuit board connected to the plurality of flexible films and including a touch driver. The amplifier may be disposed on the printed circuit board.

The first pseudo line and the second pseudo line extended from the touch driver may be connected to an input terminal of the amplifier, and an output terminal of the amplifier may be connected to the first pseudo line and the second pseudo line on the substrate.

The display device may further include a plurality of ground lines disposed on the encapsulation layer. One of the plurality of ground lines may be disposed between an edge of the encapsulation layer and the third pseudo line, and another of the plurality of ground lines may be disposed between the active area and the fifth pseudo line.

The display device may further include a gate driver overlapping any one of the plurality of ground lines.

According to one or more other embodiments of the present disclosure, there is provided display device. The display device includes a substrate including an active area and a non-active area. The display device further includes a plurality of light-emitting diodes disposed on the substrate. The display device further includes an encapsulation layer disposed on the plurality of light-emitting diodes and extending from the active area to a portion of the non-active area The display device further includes a touch unit disposed on the encapsulation layer and the substrate. The touch unit includes: a plurality of touch electrodes on the encapsulation layer, a plurality of touch lines connected to the plurality of touch electrodes, and a plurality of pseudo lines disposed in the non-active area. The plurality of pseudo lines is disposed to enclose the plurality of touch lines and the plurality of touch electrodes.

A signal supplied to the plurality of touch lines and a signal supplied to the plurality of pseudo lines may be signals of opposite phases to each other.

The display device may further include a plurality of ground lines disposed in the non-active area. Some of the plurality of pseudo lines may be disposed in an area outside the encapsulation layer, the remainder of the plurality of pseudo lines may be disposed on the encapsulation layer, and the plurality of ground lines may be disposed adjacent to the plurality of pseudo lines.

The display device may further include an amplifier connected to some of the plurality of pseudo lines disposed outside the encapsulation layer. The amplifier may be configured to amplify a signal and output the amplified signal to some of the plurality of pseudo lines.

The display device may further include a gate driver disposed in the non-active area and including a scan signal driver and a light emission signal driver. One of the plurality of ground lines may overlap the gate driver and may be disposed adjacent to the plurality of pseudo lines.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display device, comprising:
a substrate including an active area and a non-active area;
an encapsulation layer disposed on the substrate;
a plurality of pseudo lines disposed in the non-active area; and
an amplifier connected to a subset of the plurality of pseudo lines,
wherein the subset of the plurality of pseudo lines are disposed outside the encapsulation layer in the non-active area, and
wherein a remainder of the plurality of pseudo lines not in the subset of the plurality of pseudo lines are disposed on the encapsulation layer in the non-active area.

2. The display device according to claim 1, wherein the plurality of pseudo lines are disposed to enclose the active area.

3. The display device according to claim 1, wherein the plurality of pseudo lines include:
a first pseudo line disposed outside the encapsulation layer,
a second pseudo line disposed outside the encapsulation layer,
a third pseudo line disposed on the encapsulation layer,
a fourth pseudo line disposed on the encapsulation layer, and
a fifth pseudo line disposed on the encapsulation layer, and
wherein the amplifier is connected to the first pseudo line and the second pseudo line.

4. The display device according to claim 3, further comprising:
a set cover disposed under the substrate,
wherein the set cover is coupled to one or more pseudo lines of the plurality of pseudo lines.

5. The display device according to claim 3, further comprising:
a plurality of flexible films connected to the substrate; and
a printed circuit board connected to the plurality of flexible films, the printed circuit board including a touch driver,
wherein the amplifier is disposed on the printed circuit board.

6. The display device according to claim 5, wherein the first pseudo line and the second pseudo line extended from the touch driver are connected to an input terminal of the amplifier, and wherein an output terminal of the amplifier is connected to the first pseudo line and the second pseudo line on the substrate.

7. The display device according to claim 3, further comprising:
a plurality of ground lines disposed on the encapsulation layer,
wherein a first ground line of the plurality of ground lines is disposed between an edge of the encapsulation layer and the third pseudo line, and
wherein a second ground line of the plurality of ground lines is disposed between the active area and the fifth pseudo line.

8. The display device according to claim 7, further comprising:
a gate driver overlapping a ground line of the plurality of ground lines.

9. A display device, comprising:
a substrate including an active area and a non-active area;
a plurality of light-emitting diodes disposed on the substrate;
an encapsulation layer disposed on the plurality of light-emitting diodes, the encapsulation layer extending from the active area to a portion of the non-active area; and
a touch unit disposed on the encapsulation layer and the substrate,
wherein the touch unit includes:
a plurality of touch electrodes on the encapsulation layer,
a plurality of touch lines connected to the plurality of touch electrodes, and
a plurality of pseudo lines disposed in the non-active area, and
wherein the plurality of pseudo lines enclose the plurality of touch lines and the plurality of touch electrodes.

10. The display device according to claim 9, wherein a first phase of a first signal supplied to the plurality of touch lines is opposite to a second phase of a second signal supplied to the plurality of pseudo lines.

11. The display device according to claim 9, further comprising:
a plurality of ground lines disposed in the non-active area,
wherein a subset of the plurality of pseudo lines are disposed in an area outside the encapsulation layer,
wherein a remainder of the plurality of pseudo lines not in the subset of the plurality of pseudo lines are disposed on the encapsulation layer, and
wherein the plurality of ground lines are disposed adjacent to the plurality of pseudo lines.

12. The display device according to claim 11, further comprising:
an amplifier connected to the subset of the plurality of pseudo lines disposed in the area outside the encapsulation layer,
wherein the amplifier is configured to amplify a signal and output the amplified signal to the subset of the plurality of pseudo lines.

13. The display device according to claim 11, further comprising:
a gate driver disposed in the non-active area, the gate driver including a scan signal driver and a light emission signal driver,
wherein a first ground line of the plurality of ground lines overlaps the gate driver and is disposed adjacent to the plurality of pseudo lines.
